(19) United States
(12) Patent Application Publication
(10) Pub. No.: US 2026/0060059 A1
(43) Pub. Date: Feb. 26, 2026

(54) SEMICONDUCTOR DEVICE, SEMICONDUCTOR MODULE, AND METHOD OF MANUFACTURING SEMICONDUCTOR DEVICE

(71) Applicant: FUJI ELECTRIC CO., LTD., Kawasaki-shi (JP)

(72) Inventors: Motoyoshi KUBOUCHI, Matsumoto-city (JP); Shuntaro YAGUCHI, Matsumoto-city (JP); Takamasa WAKABAYASHI, Matsumoto-city (JP); Takashi YOSHIMURA, Matsumoto-city (JP); Makoto SHIMOSAWA, Matsumoto-city (JP)

(73) Assignee: FUJI ELECTRIC CO., LTD., Kawasaki-shi (JP)

(21) Appl. No.: 19/376,700

(22) Filed: Oct. 31, 2025

Related U.S. Application Data
(63) Continuation of application No. PCT/JP2024/039576, filed on Nov. 7, 2024.

(30) Foreign Application Priority Data
Nov. 8, 2023 (JP) 2023-191165

(51) Int. Cl. H01L 23/535; H01L 21/768; H01L 23/00; H01L 23/049; H01L 23/31; H01L 23/373; H10D 62/53; H10D 84/00

(52) U.S. Cl. CPC H01L 23/535; H01L 21/7684; H01L 21/76846; H01L 21/76895; H01L 23/049; H01L 23/3107; H01L 23/3735; H01L 24/32; H01L 24/48; H01L 24/73; H10D 62/53; H10D 84/161; H01L 2224/32225; H01L 2224/48175; H01L 2224/48225; H01L 2224/73265; H01L 2924/13055

(57) ABSTRACT

A semiconductor device, including: a semiconductor substrate having a main surface; an interlayer insulating film provided on the main surface of the semiconductor substrate; a contact hole penetrating through the interlayer insulating film to reach the semiconductor substrate; a plug electrode embedded in the contact hole; a first barrier metal provided on the interlayer insulating film, the first barrier metal being apart from the plug electrode; and a front electrode provided on the first barrier metal and the plug electrode.

### CROSS REFERENCE TO RELATED APPLICATIONS

This is a continuation application of International Application PCT/JP2024/039576 filed on Nov. 7, 2024, which claims priority from a Japanese Patent Application No. 2023-191165 filed on Nov. 8, 2023, the contents of which are incorporated herein by reference.

### BACKGROUND OF THE INVENTION

### 1. Field of the Invention

Embodiments of the disclosure relate to a semiconductor device, a semiconductor module, and a method of manufacturing a semiconductor device.

### 2. Description of the Related Art

Conventionally, a semiconductor device is known in which an opening is provided in a barrier metal layer on an interlayer insulating film to increase the amount of hydrogen that reaches the substrate and suppress a decrease in threshold voltage. Also known is a semiconductor device in which a first metal film of the barrier metal contains a Group VIII metal material such as nickel (Ni) or cobalt (Co), so that hydrogen reaches a silicon surface damaged by electron beam irradiation or the like during hydrogen annealing. For example, refer to Japanese Laid-Open Patent Publication No. 2005-327799 and Japanese Patent No. 5672719.

### SUMMARY OF THE INVENTION

A semiconductor device according to the present disclosure includes: a semiconductor substrate having a main surface; an interlayer insulating film provided on the main surface of the semiconductor substrate; a contact hole penetrating through the interlayer insulating film to reach the semiconductor substrate; a plug electrode embedded in the contact hole; a first barrier metal provided on the interlayer insulating film, the first barrier metal being apart from the plug electrode; and a front electrode provided on the first barrier metal and the plug electrode.

Objects, features, and advantages of the present disclosure are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor device according to a first embodiment.

FIG. 2 is a cross-sectional view depicting a structure of an electrode of the semiconductor device according to the first embodiment.

FIG. 3 is a cross-sectional view depicting a structure of a semiconductor module according to the first embodiment.

FIG. 4 is a cross-sectional view depicting effects of the semiconductor device according to the first embodiment.

FIG. 5 is a cross-sectional view depicting effects of the semiconductor device according to the first embodiment.

FIG. 6 is a cross-sectional view depicting effects of the semiconductor device according to the first embodiment.

FIG. 7 is a cross-sectional view schematically depicting electrode formation in a method of manufacturing the semiconductor device according to the first embodiment.

FIG. 8 is a cross-sectional view schematically depicting electrode formation in the method of manufacturing the semiconductor device according to the first embodiment.

FIG. 9 is a cross-sectional view schematically depicting electrode formation in the method of manufacturing the semiconductor device according to the first embodiment.

FIG. 10 is a cross-sectional view schematically depicting electrode formation in the method of manufacturing the semiconductor device according to the first embodiment.

FIG. 11 is a cross-sectional view schematically depicting electrode formation in the method of manufacturing the semiconductor device according to the first embodiment.

FIG. 12 is a cross-sectional view depicting other structures of the electrodes of the semiconductor device according to the first embodiment.

FIG. 13 is a cross-sectional view depicting other structures of the electrodes of the semiconductor device according to the first embodiment.

FIG. 14 is a cross-sectional view depicting other structures of the electrodes of the semiconductor device according to the first embodiment.

FIG. 15 is a cross-sectional view depicting other structures of the electrodes of the semiconductor device according to the first embodiment.

FIG. 16 is a cross-sectional view depicting other structures of the electrodes of the semiconductor device according to the first embodiment.

FIG. 17 is a cross-sectional view depicting other structures of the electrodes of the semiconductor device according to the first embodiment.

FIG. 18 is a cross-sectional view depicting other structures of the electrodes of the semiconductor device according to the first embodiment.

FIG. 19 is a cross-sectional view depicting a structure of an electrode of a semiconductor device according to a second embodiment.

FIG. 20 is a cross-sectional view depicting another structure of an electrode of a semiconductor device according to a third embodiment.

FIG. 21 is a cross-sectional view depicting a structure near a signal electrode pad of a semiconductor device according to a fourth embodiment.

FIG. 22 is a cross-sectional view depicting the structure near the signal electrode pad of the semiconductor device according to the fourth embodiment.

FIG. 23 is a cross-sectional view depicting the structure near the signal electrode pad of the semiconductor device according to the fourth embodiment.

FIG. 24 is a cross-sectional view schematically depicting electrode formation according to a method of manufacturing a conventional semiconductor device.

FIG. 25 is a cross-sectional view schematically depicting electrode formation according to the method of manufacturing the conventional semiconductor device.

FIG. 26 is a cross-sectional view schematically depicting electrode formation according to the method of manufacturing the conventional semiconductor device.

FIG. 27 is a cross-sectional view schematically depicting electrode formation according to the method of manufacturing the conventional semiconductor device.

FIG. 28 is a cross-sectional view schematically depicting electrode formation according to the method of manufacturing the conventional semiconductor device.

FIG. 29 is a cross-sectional view schematically depicting electrode formation according to the method of manufacturing the conventional semiconductor device.

FIG. 30 is a cross-sectional view schematically depicting electrode formation according to the method of manufacturing the conventional semiconductor device.

FIG. 31 is a cross-sectional view depicting a decrease in Vth caused by a partial barrier metal removal method of the conventional semiconductor device.

FIG. 32 is a cross-sectional view depicting a Vth decrease when an entire barrier metal leaving method is used in the conventional semiconductor device.

FIG. 33 is a cross-sectional view depicting the Vth decrease when the entire barrier metal leaving method is used in the conventional semiconductor device.

FIG. 34 is a cross-sectional view depicting a structure near a signal electrode pad of the conventional semiconductor device.

### DETAILED DESCRIPTION OF THE INVENTION

First, problems associated with the conventional techniques are discussed. Conventional semiconductor devices have a problem of decreased Vth due to defects in the front electrode, which allows ions to reach the gate insulating film through the defects in the front electrode, or due to defects formed on the gate insulating film. A semiconductor device, a semiconductor module, and a method of manufacturing a semiconductor device according to the present disclosure may suppress decreases in Vth attributable to defects in the front electrode or defects on the gate insulating film.

Embodiments of a semiconductor device, a semiconductor module, and a method of manufacturing a semiconductor device according to the present disclosure will be described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical will be given the same reference numerals and will not be repeatedly described. Further, with consideration of variation in manufacturing, description indicating the same or equal may be within 5%.

Before description of a first embodiment according to the present disclosure, a conventional semiconductor device manufacturing method is described. A conventional method of manufacturing a semiconductor device is described using a reverse conducting insulated gate bipolar transistor (RC-IGBT) as an example. The RC-IGBT is formed by integrating, for example, an IGBT having a trench gate structure and a freewheeling diode (FWD) connected in antiparallel to the IGBT on a single semiconductor substrate (semiconductor chip).

First, a typically employed thick n type semiconductor substrate (semiconductor wafer) is prepared. Next, a surface device structure such as a metal oxide semiconductor (MOS) gate (an insulated metal-oxide-semiconductor gate) is formed using a general method. For example, an n-type accumulation layer, a p-type base region, a trench, an n⁺-type emitter region, a p⁺-type contact region, a gate insulating film, a gate electrode, etc. are formed on the front surface of an n⁻-type semiconductor substrate, which is an n⁻-type semiconductor drift layer. Hereinafter, an n⁻-type semiconductor substrate with a surface device structure formed thereon is referred to as a semiconductor wafer 110. Next, an interlayer insulating film 109 having two layers, for example, a BPSG film and an HTO film, is deposited (formed) on the surface of the semiconductor wafer 110 so as to cover the gate electrode.

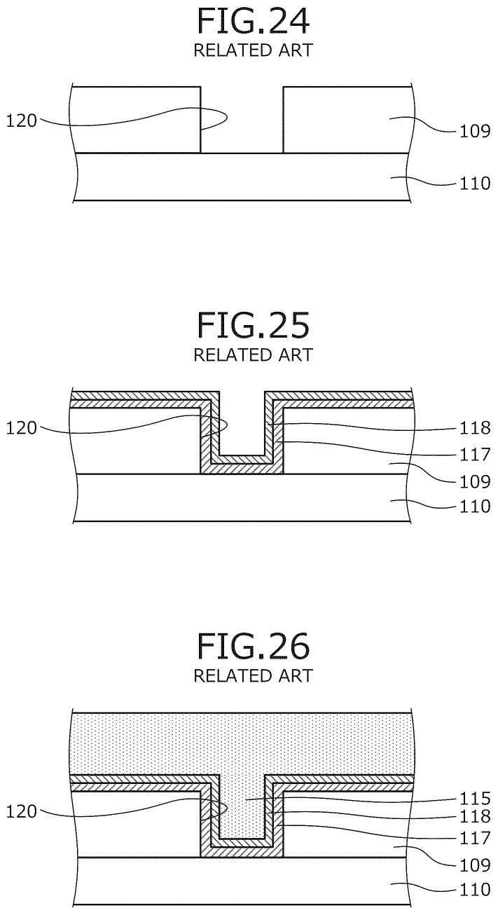

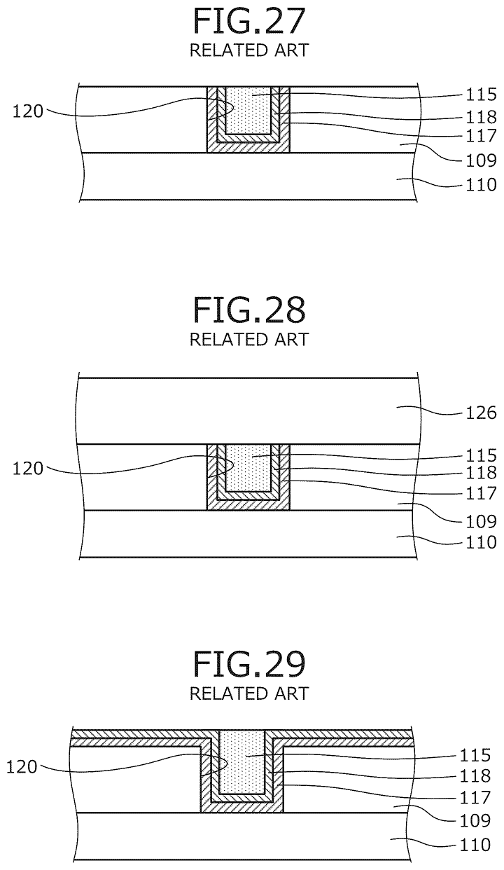

FIGS. 24, 25, 26, 27, 28, 29, and 30 are cross-sectional views schematically depicting electrode formation according to a method of manufacturing a conventional semiconductor device. Next, as depicted in FIG. 24, the interlayer insulating film 109 is patterned, thereby forming a contact hole 120. Next, as depicted in FIG. 25, a titanium (Ti) film 117 and a titanium nitride (TiN) film 118, which serve as barrier metals, are formed in the mentioned order on the interlayer insulating film 109 by sputtering. Next, as depicted in FIG. 26, a contact plug 115 formed by a tungsten (W) film is formed on the barrier metal. Next, as depicted in FIG. 27, portions other than the Ti film 117, the TIN film 118, and the contact plug 115 in the contact hole 120 are removed by etching. Next, as depicted in FIG. 28, a front-surface metal film 126 containing, for example, an aluminum silicon (Al—Si) alloy is formed by, for example, sputtering to cover the entire surface of the interlayer insulating film 109 so as to be in contact with the contact plug 115 in the contact hole 120.

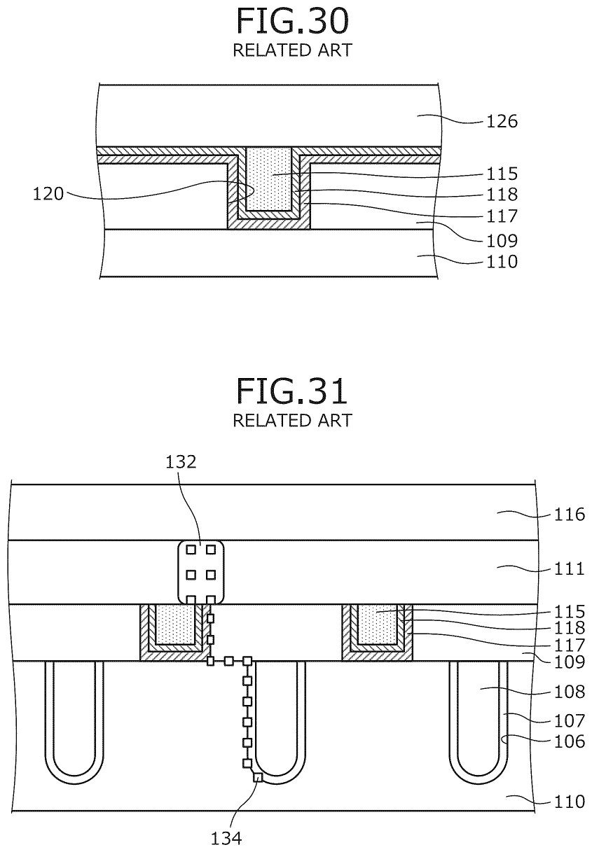

In addition to the method of removing the barrier metal (Ti film 117, TiN film 118) on the interlayer insulating film 109 (hereinafter referred to as a partial barrier metal removal method), there is also a method of leaving the barrier metal (Ti film 117, TiN film 118) on the interlayer insulating film 109 (hereinafter referred to as an entire barrier metal leaving method). In this case, as depicted in FIG. 26, the contact plug 115 is formed on the barrier metal, and then, as depicted in FIG. 29, the contact plug 115 is removed by etching except for a portion thereof in the contact hole 120. Next, as depicted in FIG. 30, the front-surface metal film 126 is formed by, for example, sputtering to cover the entire surface of the interlayer insulating film 109 so as to be in contact with the contact plug 115 in the contact hole 120.

Next, the front-surface metal film 126 is patterned. Next, the front-surface metal film 126 is annealed thereby forming front electrodes 111 (emitter electrode, anode electrode, and each signal electrode pad). Next, the n⁻-type semiconductor substrate is ground from a back surface thereof, reducing the thickness thereof to a product thickness used for a semiconductor device. Next, a back-surface device structure is formed at the back surface of the n⁻-type semiconductor substrate after grinding. Next, a passivation film is formed on the front surface of the semiconductor wafer thereby covering the edge termination region. Next, the passivation film is patterned, exposing the emitter electrode, anode electrode, and each signal electrode pad. Next, hydrogen or helium defects that act as lifetime killers are introduced in to the n⁻-type drift region thereby forming a lifetime killer control region.

Next, back electrodes (a collector electrode and a cathode electrode) are formed at the back surface of the n⁻-type semiconductor substrate. Next, the n⁻-type semiconductor substrate is cut (diced) into individual chips, thereby completing RC-IGBT chips (semiconductor chips).

In the method of manufacturing the conventional semiconductor device, forming the front electrodes using a partial barrier metal removal method may result in a decrease in Vth (threshold voltage). FIG. 31 is a cross-sectional view depicting a decrease in Vth caused by the partial barrier metal removal method of a conventional semiconductor device. In conventional semiconductor devices, a front electrode defect 132 occurs in the front electrode 111 due to stress migration or the like. In an instance in which this front electrode defect 132 reaches the interlayer insulating film 109 as depicted in FIG. 31, ions 134 in a package resin 116 pass through the front electrode defect 132 and reach a gate insulating film 107, resulting in a decrease in Vth.

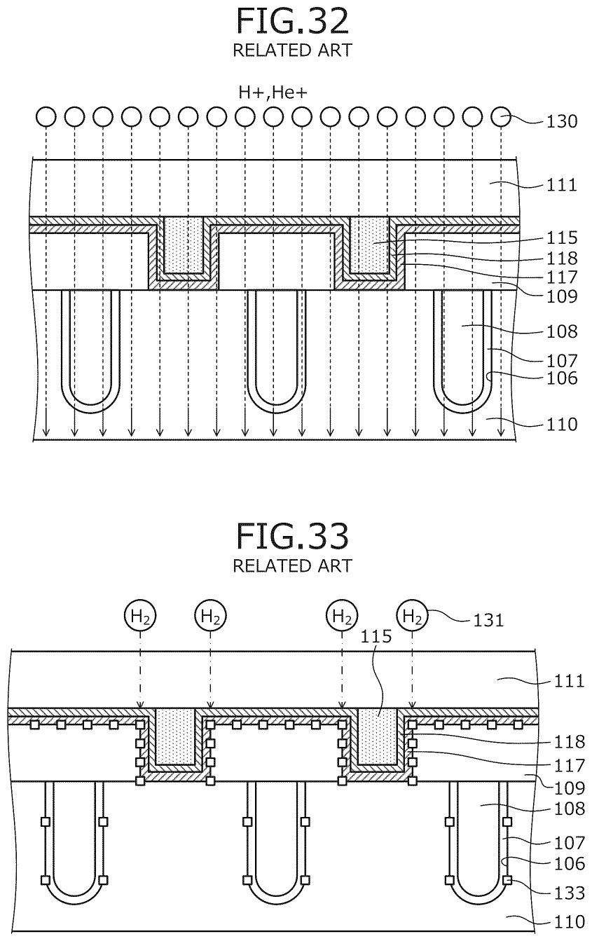

Furthermore, when the front electrodes are formed using the method of manufacturing the conventional semiconductor device in which the barrier metal is left on the entire surface, the ions 134 from the package resin 116 do not reach the gate insulating film 107 due to the presence of the barrier metal on the entire surface, and a Vth decrease attributable to the front electrode defect 132 does not occur. However, even when the surface electrode is formed using the entire barrier metal leaving method, a Vth decrease may occur. FIGS. 32 and 33 are cross-sectional views depicting a Vth decrease when the entire barrier metal leaving method is used in a conventional semiconductor device.

As depicted in FIG. 32, when charged particles (H⁺, He⁺, e⁻) 130 are implanted to create a lifetime controlled region, the gate insulating film 107 is damaged, resulting in a defect 133. When the surface electrode is formed using the partial barrier metal removal method, the defect 133 is repaired by supplying heat and hydrogen (H₂) to the defect portion during subsequent annealing. However, with the entire barrier metal leaving method in which the barrier metal is left on the entire surface of the interlayer insulating film 109, as depicted in FIG. 33, hydrogen 131 that would be supplied to the defect portion by annealing is absorbed by Ti in the barrier metal and does not reach the defect 133 on the gate insulating film 107 and thus, the defect 133 does not recover and resulting in a decrease in Vth.

Even in an instance in which formation of a lifetime controlled region is omitted, if the defect 133 is generated in the gate insulating film 107 during the manufacturing flow, the defect 133 may not recover by annealing, causing a decrease in Vth, as described above.

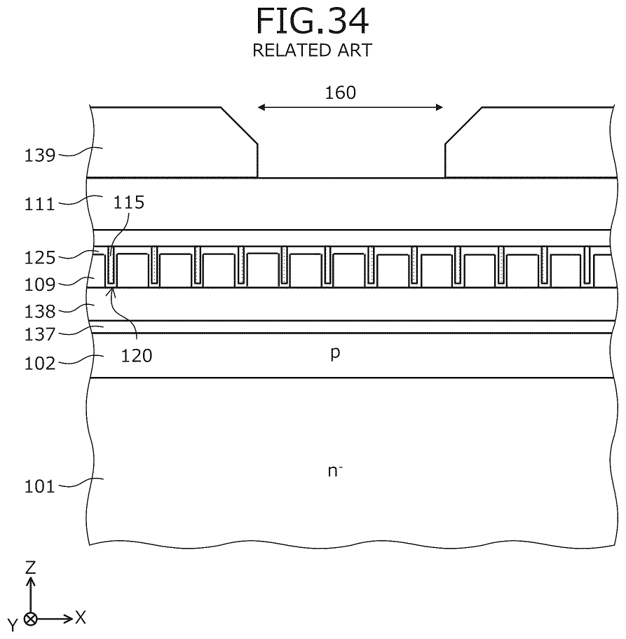

FIG. 34 is a cross-sectional view depicting the structure near a signal electrode pad of the conventional semiconductor device. The signal electrode pad is, for example, a gate pad. As depicted in FIG. 34, a passivation film 139 is provided on the front electrode 111, and a signal electrode pad 160 is exposed through an opening in the passivation film 139. Below the signal electrode pad 160, an insulating film 137 is provided on an n-type drift region 101 and a p-type base region 102, electrically insulating the n⁻-type drift region 101 and the p-type base region 102 from a connection portion 138. For example, in the case of a gate pad, the insulating film 137 may be formed concurrently with the gate insulating film 107, and the connection portion 138 may be formed concurrently with a gate electrode 108. The insulating film 137 may be connected to the gate insulating film 107, and the connection portion 138 may be connected to the gate electrode 108.

Here, when a barrier metal 125 is left on the interlayer insulating film 109 in the active region, the barrier metal 125 is also left between the front electrode 111 and the interlayer insulating film 109 near the signal electrode pad 160. In this case, when a conductive wire is connected to the signal electrode pad 160 during mounting, the barrier metal 125 may peel off, and the front electrode 111 may also peel off. For this reason, polysilicon connection portions 138 are left below the signal electrode pad 160, and the barrier metal 125 is anchored by the connection portions 138 and the contact plugs 115, thereby preventing peeling of the barrier metal 125. However, in an instance in which the defect 133 is generated in the gate insulating film 107 in the active region, the defect 133 may not be repaired by annealing because the barrier metal 125 on the interlayer insulating film 109 below the signal electrode pad 160 contains Ti and a decrease in Vth may result.

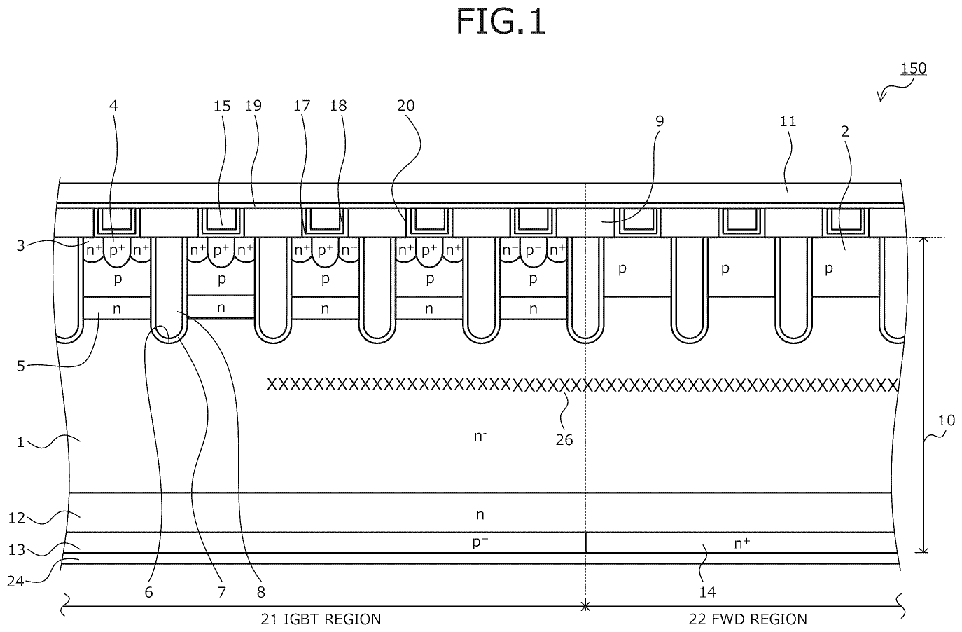

A semiconductor device, a semiconductor module, and a method of manufacturing a semiconductor device according to the first embodiment that solves the above problems is described below. FIG. 1 is a cross-sectional view depicting a structure of a semiconductor device according to the first embodiment. The structure of the semiconductor device according to the first embodiment will be described using a trench-type RC-IGBT 150 as an example. The semiconductor device according to the first embodiment depicted in FIG. 1 is the RC-IGBT 150 in which an IGBT with a trench gate structure and a diode connected in anti-parallel to the IGBT are integrated on a single semiconductor substrate (semiconductor chip). The RC-IGBT 150 has an active region, which is a region through which current flows while the RC-IGBT 150 is energized, and an edge termination region surrounding the active region, however, FIG. 1 depicts only the active region.

In the RC-IGBT 150, an IGBT region (transistor portion) 21, which serves as an operating region of the IGBT, and an FWD region (diode portion) 22, which serves as an operating region of the diode, are disposed in parallel on the same semiconductor substrate as the active region.

In a semiconductor wafer 10 in the active region, an n-type accumulation layer 5 may be provided in the n-type drift region 1, at a front surface (first main surface) thereof. The n-type accumulation layer 5 is a so-called charge storage layer (CSL) that reduces the spreading resistance of carriers. A p-type base region (first dopant layer) 2 is provided on the n-type accumulation layer 5, extending from the IGBT region 21 to the FWD region 22. The p-type base region 2 functions as a p-type anode region in the FWD region 22. Trenches (grooves) 6 that penetrate through the p-type base region 2 and reach the n-type drift layer 1 are provided. The trenches 6 are provided in the IGBT region 21 and the FWD region 22, and n⁺-type emitter regions (second dopant layers) 3 are provided on both sides thereof in the IGBT region 21. The trenches 6 are disposed at predetermined intervals in a striped layout in a plan view, for example, dividing the p-type base region 2 into multiple subregions (mesa portions). Gate insulating films 7 are provided in the trenches 6 along inner walls of the trenches 6, respectively, and gate electrodes 8 are provided on the gate insulating films 7, respectively. At least some of the gate electrodes 8 may be connected to a gate finger wired from the gate electrode pad to a part of the edge termination region outside the scope of FIG. 1.

In the IGBT region 21, the n⁺-type emitter regions 3 are selectively provided in each mesa portion in the p-type base region 2. The n⁺-type emitter regions 3 face the gate electrodes 8 across the gate insulating films 7 provided on the inner walls of the trenches 6. In the mesa portions, p⁺-type contact regions 4 may be provided. In this case, the n⁺-type emitter regions 3 and the p⁺-type contact regions 4 are in contact with each other. In the FWD region 22, the p-type base region 2 is free of the n⁺-type emitter regions 3 and the p⁺-type contact regions 4. A front electrode 11 is in contact with the n⁺-type emitter regions 3 through contact holes 20 and is electrically insulated from the gate electrodes 8 by an interlayer insulating film 9. Openings may be selectively provided in the n⁺-type emitter regions 3, and the front electrode 11 and the p-type base region 2 may be electrically connected through the opening. In an instance in which the p⁺-type contact regions 4 are provided, the front electrode 11 and the p⁺-type contact regions 4 may be electrically connected. The front electrode 11 functions as an emitter electrode in the IGBT region 21 and as an anode electrode in the FWD region 22. Between the front electrode 11 and the interlayer insulating film 9, for example, a Ti film 17 and a first TiN film 18 are provided as barrier metal to prevent diffusion of metal atoms from the front electrode 11 to the gate electrodes 8. Furthermore, a second TiN film 19 is provided as barrier metal between the interlayer insulating film 9 and the front electrode 11. Note that some of the gate electrodes 8 may be connected to the front electrode 11 in the active region or edge termination region without connection to the gate finger.

Alternatively, a structure may be employed in which contact plugs are embedded in the contact holes 20 formed in the interlayer insulating film 9. The contact plugs are formed, for example, by a metal film containing tungsten (W), which has high embedding properties. The front electrode 11 is formed of an Al film or an Al alloy film such as Al—Si. The front electrode 11 may also have a stacked structure of W and an Al or Al alloy film sequentially from the second TiN film 19 side. Providing W on the second TiN film 19 as described may improve mechanical strength. In cases such as when the cell pitch is wide, a structure in which the front electrode 11 is embedded the contact holes 20 without forming a contact plug may be used. Alternatively, the front electrode 11 may contain copper (Cu) or an alloy containing Cu, or a metal film in which, for example, Ni or gold (Au) is stacked on an Al or Al alloy film. Hereinafter, the contact plug or the front electrode 11 in the contact holes 20 will be referred to as a plug electrode 15. Note that in FIG. 1 and subsequent figures, while the plug electrode 15 is depicted as having a rectangular cross section with a top surface flush with the interlayer insulating film 9, this is not a limitation. The side surfaces thereof may be tapered. The top surface may not be flush with the interlayer insulating film 9 and may be recessed. The bottom surface thereof may have a so-called trench contact structure in which the semiconductor wafer 10 is recessed to be lower than the lower surface of interlayer insulating film 9.

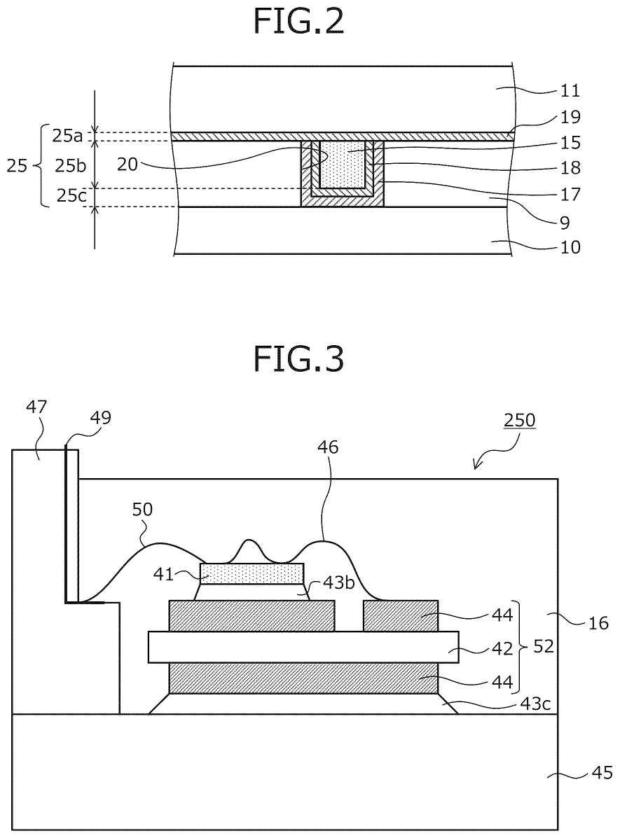

FIG. 2 is a cross-sectional view depicting the structure of an electrode of the semiconductor device according to the first embodiment. In the first embodiment, each barrier metal 25 is configured by a first barrier metal 25a formed on the plug electrode 15 and the interlayer insulating film 9, a second barrier metal 25b formed between the side surface of the plug electrode 15 and the interlayer insulating film 9, and a third barrier metal 25c formed between the plug electrode 15 and the semiconductor wafer 10.

The first barrier metal 25a is, for example, the second TiN film 19, and the second barrier metal 25b and the third barrier metal 25c are, for example, two-layer films formed by stacking the Ti film 17 and the first TiN film 18 in the mentioned order. The Ti film 17 ensures contact and adhesion to Si. The first TiN film 18 and the second TiN film 19 prevent Al diffusion from the front electrode 11, prevent erosion by the WF₆ gas used in W-CVD, and ensure adhesion to W of the plug electrode 15. Instead of the first TiN film 18 and the second TiN film 19, a nickel (Ni) film or a tantalum (Ta) film may be used. The first TiN film 18 and the second TiN film 19 have a thickness in a range of, for example, 1 nm to 400 nm and preferably, the thickness may be in a range of 1 nm to 200 nm. The third barrier metal 25c may also contain a material formed by chemically changing the barrier metal (initial barrier metal) deposited in contact with the semiconductor wafer 10, by a heat treatment. Here, the chemical change may refer to the formation of an alloy with the underlying Si. On the other hand, the second barrier metal 25b may not undergo a chemical change through heat treatment. Here, “not undergoing a chemical change” does not mean “no reaction at all.” An instance of “not undergoing a chemical change” may also include a slight reaction compared to the reaction of the third barrier metal 25c, in which most of the Ti film forms an alloy with Si. For example, the heat treatment may be performed after the formation of the first TiN film 18, and this heat treatment may make the first TiN film 18 of the second barrier metal 25b denser than before the heat treatment. Furthermore, this heat treatment may be performed, for example, after the formation of the Ti film 17 but before the formation of the first TiN film 18. This heat treatment may chemically change the surface of the Ti film 17, for example, forming a thin TIN film on the surface of the Ti film 17. That is, nitridation may occur as a chemical change. The first barrier metal 25a may be formed by chemically modifying the second TiN film 19, the second barrier metal 25b may be formed by chemically modifying the Ti film 17 and the first TiN film 18, and the third barrier metal 25c may be formed by chemically modifying the Ti film 17 and the first TiN film 18, with each having a different composition. In particular, when the reaction progresses due to heat treatment, the Ti film 17 may be nitrided to a TiN film. In this case, the first barrier metal 25a and the second barrier metal 25b may have the same composition. Even in this case, the first barrier metal 25a and the second barrier metal 25b may have different thicknesses.

Returning to the description of FIG. 1, an n-type field stop (FS) layer 12 is provided in the n-type drift region 1, at the back side of the substrate. The n-type FS layer 12 has the function of suppressing the spreading of a depletion layer that spreads from a pn junction between the p-type base region 2 and the n-type drift region 1, in direction to a p⁺-type collector region 13 (described later) during an off-state.

Furthermore, in the FWD region 22 in the n-type drift region 1, a lifetime controlled region 26 may be provided at a position shallower from the front surface of the n-type drift region 1 than is the n-type FS layer 12. The lifetime controlled region 26 is formed by introducing lattice defects (indicated by x marks) such as vacancies (V) that act as lifetime killers through irradiation with hydrogen (H) or helium (He). Formation of the lifetime controlled region 26 may reduce loss in the device. The lifetime controlled region 26 may extend to a vicinity of the boundary between the IGBT region 21 and the FWD region 22. The lifetime controlled region 26 may also extend to the chip end of the edge termination region. When the lifetime controlled region 26 is formed by irradiation with a highly transmissive particle beam such as an electron beam, lattice defects are formed substantially uniformly from the front surface to the back surface of the substrate. Even in this case, the depth position of the lifetime controlled region 26 may be assumed to be relatively closer to the front surface of the substrate than the back surface thereof.

In the n-type drift region 1, at a position shallower from the back surface (second main surface) of the n-type drift region 1 than is the n-type FS layer 12, the p⁺-type collector region 13 is provided in the IGBT region 21 and an n⁺-type cathode region 14 is provided in the FWD region 22. The n⁺-type cathode region 14 is adjacent to the p⁺-type collector region 13. A back electrode 24 is provided at surfaces of the p⁺-type collector region 13 and the n⁺-type cathode region 14. The back electrode 24 functions as a collector electrode in the IGBT region 21 and as a cathode electrode in the FWD region 22.

FIG. 3 is a cross-sectional view depicting the structure of a semiconductor module according to the first embodiment. In the present specification, a device formed on the semiconductor wafer 10 that is cut (diced) into individual chips having the device there on is referred to as a semiconductor device, and a device that has been processed further and is housed in a case or the like and is ready for shipment is referred to as a semiconductor module. As depicted in FIG. 3, a semiconductor module 250 includes a semiconductor device element 41, which is a semiconductor chip, an insulating substrate 42, bonding materials 43 b and 43 c, an electrode pattern 44, a metal substrate 45, a conductive wire 46, a resin case 47, a sealing resin 16, a metal terminal 49, and a conductive wire 50.

The semiconductor device element 41 is a semiconductor element such as an RC-IGBT, a metal oxide semiconductor field effect transistor (MOSFET) having an insulated gate with a three-layer metal-oxide-semiconductor structure, or a diode chip. The semiconductor device element 41 may be a vertical semiconductor element in which a main current flows in the thickness direction of the chip. Electrode patterns 44, formed by a Cu plate or the like, are provided at the front surface (semiconductor device element 41 side) and the back surface (metal substrate 45 side) of the insulating substrate 42, such as a ceramic substrate, which ensures insulation. A stacked substrate 52 is the insulating substrate 42 having the electrode pattern 44 on at least one surface thereof. The semiconductor device element 41 is bonded to the electrode pattern 44 on the front surface by a bonding material 43b such as solder. The metal substrate 45 having heat dissipation fins (not depicted) is bonded to the electrode pattern 44 on the back surface by a bonding material 43c such as solder. As electrical connection wiring, one end of the conductive wire 46 containing a metal primarily containing Al, Cu, or Au is bonded, using ultrasound, to the top surface of the semiconductor device element 41 (the surface opposite to the surface in contact with the bonding material 43b). The other end of the conductive wire 46 is bonded to the electrode pattern 44 by the bonding material 43b using ultrasound. The conductive wire 46 may be a wire having a circular cross section or may be a flat ribbon. The conductive wire 46 may be bonded to the top surface of the semiconductor device element 41 or the electrode pattern 44 by laser bonding. In another example, instead of the conductive wire 46, a lead frame may be bonded to the top surface of the semiconductor device element 41 or the electrode pattern 44 using a bonding material such as solder.

The resin case 47 is combined with a stacked assembly in which the semiconductor device element 41, the stacked substrate 52, and the metal substrate 45 are stacked. For example, the resin case 47 is bonded to the stacked assembly using an adhesive such as silicone. The interior of the resin case 47 is filled with the sealing resin 16 such as a hard resin such as epoxy, or a gel to insulate and protect the semiconductor device element 41 on the stacked substrate 52. The conductive wire 50 that carries a signal current connects the semiconductor device 150 and the metal terminal 49. The metal terminal 49 penetrates the resin case 47 and protrudes to the outside. The electrode pattern 44 may also be connected to the metal terminal 49 by a conductive wire or the like in a region not depicted.

A caseless semiconductor module not having a case may also be used. Although not depicted, an example of the structure of a caseless semiconductor module includes, for example, implant pins and a printed circuit board bonded to the implant pins instead of the conductive wires 46 and 50 in FIG. 3, and the components including these are sealed with a thermosetting resin sealing layer. In this case, the sealed components including the stacked substrate 52, semiconductor device element 41, implant pins, and printed circuit board are assembled, the sealed components are placed in an appropriate mold, and a thermosetting resin composition constituting the thermosetting resin sealing layer is filled into the mold and cured. Examples of molding methods for such a sealed body include vacuum casting, transfer molding, liquid transfer molding, and potting, but are not limited to specific molding methods.

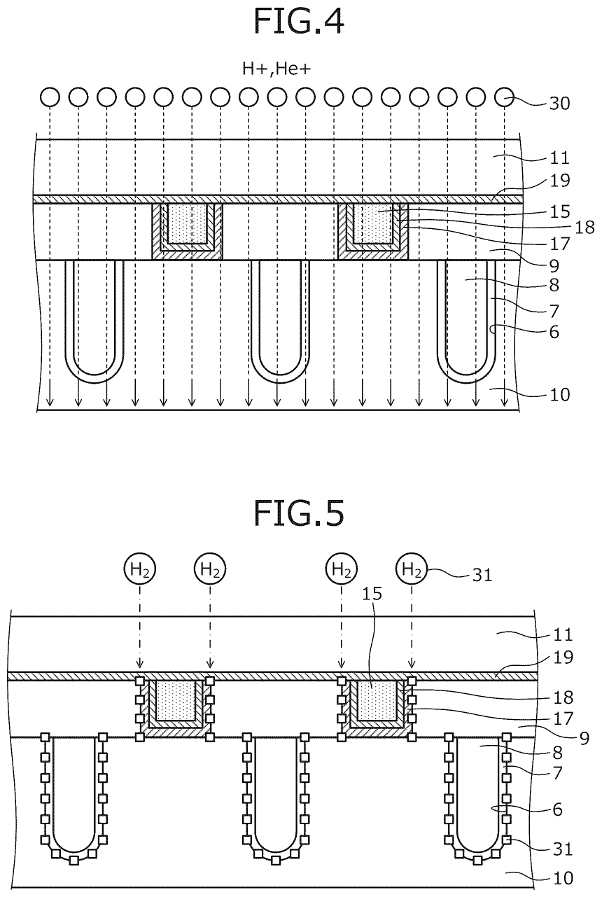

FIGS. 4, 5, and 6 are cross-sectional views depicting effects of the semiconductor device according to the first embodiment. As depicted in FIG. 4, when charged particles (H⁺, He⁺, e⁻) 30 are injected from the front surface side to create the lifetime controlled region 26, the gate insulating films 7 through which the charged particles 30 pass are damaged, resulting in defects. Furthermore, when the charged particles 30 are implanted from the back surface to create the lifetime controlled region 26, defects are generated by the charged particles 30 that pass through the lifetime controlled region 26 and reach the gate insulating films 7. In the semiconductor device according to the first embodiment, as depicted in FIG. 5, the absence of the Ti film on the interlayer insulating film 9 curbs hydrogen (H₂) absorption, and subsequent annealing supplies heat and hydrogen 31 to the defect portion, thereby repairing the defect. This makes it possible to suppress a decrease in Vth due to the defect.

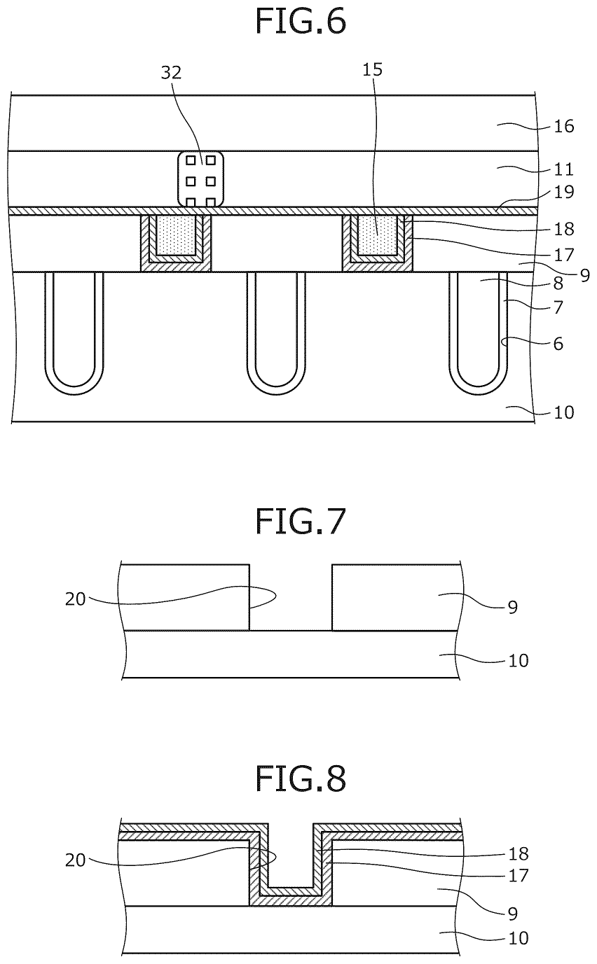

Furthermore, as depicted in FIG. 6, even when a front electrode defect 32 occurs in the front electrode 11 due to stress migration or the like, sandwiching the second TiN film 19 between the interlayer insulating film 9 and the plug electrode 15 and the front electrode 11 may ions in the package resin 16 from reaching the gate insulating films 7 through the front electrode defect 32, thereby suppressing a decrease in Vth due to the front electrode defect 32.

Next, a method of manufacturing the semiconductor device according to the first embodiment will be described. The following method of manufacturing the semiconductor device may be carried out with appropriate modifications in content and order. First, an n⁻-type semiconductor wafer 10 constituting an n⁻-type drift region 1 is prepared. A material of the semiconductor wafer 10 may be silicon (Si), silicon carbide (SiC), gallium nitride (GaN), diamond (C), or gallium oxide (Ga₂O₃), as a single element or a compound. The following description will be given using a silicon wafer as an example.

Next, a process including photolithography and ion implantation is repeated under different conditions thereby forming a surface device structure, including a MOS structure, in the semiconductor wafer 10, at the front surface thereof. For example, first, the p-type base region 2, the n⁺-type emitter regions 3, and the p⁺-type contact regions 4 of the IGBT are formed. The p-type base region 2 is formed in an entire area of the active region, from the IGBT region 21 to the FWD region 22. The p-type base region 2 also serves as a p-type anode region, in the FWD region 22. The n⁺-type emitter regions 3 and the p⁺-type contact regions 4 are selectively formed in the p-type base region 2, in the IGBT region 21.

A portion of the semiconductor wafer 10 other than the p-type base region 2, the n-type field stop (FS) layer 12 (described later), the p⁺-type collector region 13, and the n⁺-type cathode region 14 constitutes the n⁻-type drift region 1. In the IGBT region 21, the n-type accumulation layer 5 may be formed between the n⁻-type drift region 1 and the p-type base region 2. The n-type accumulation layer 5 functions as a barrier to minority carriers (holes) in the n⁻-type drift region 1 when the IGBT is conductive, and accumulates minority carriers in the n⁻-type drift region 1.

Next, the front surface of the semiconductor wafer 10 is thermally oxidized thereby forming a field oxide film covering the front surface of the semiconductor wafer 10, in the edge termination region. Next, in the IGBT region 21, the trenches 6, which penetrate through the n⁺-type emitter regions 3, the p-type base region 2, and the n-type accumulation layer 5 and reach the n-type drift region 1 are formed by photolithography and etching. The trenches 6 are disposed, for example, in a stripe-like layout extending in a direction (depth direction in FIG. 1) orthogonal to the direction in which the IGBT region 21 and the FWD region 22 are arranged (transverse direction in FIG. 1) when viewed from the front surface of the semiconductor wafer 10.

Furthermore, the trenches 6 are also formed in the FWD region 22 in the same layout as the IGBT region 21. In the FWD region 22, the trenches 6 penetrate through the p-type base region 2 (p-type anode region) and reach the n⁻-type drift region 1. Next, the gate insulating films 7 are formed, respectively, along the inner walls of the trenches 6, for example, by thermal oxidation. Next, a polysilicon (poly-Si) layer is formed at the front surface of the semiconductor wafer 10 so as to be embedded in the trenches 6. Next, the polysilicon layer is etched back, for example, leaving portions thereof that constitute the gate electrodes 8 in the trenches 6.

The p-type base region 2, the n⁺-type emitter regions 3, the p⁺-type contact regions 4, the trenches 6, the gate insulating films 7, and the gate electrodes 8 constitute MOS gates with a trench gate structure. After the gate electrodes 8 are formed, the n⁺-type emitter regions 3, the p⁺-type contact regions 4, and the n-type accumulation layer 5 may be formed. The n⁺-type emitter regions 3 may be disposed in at least one mesa region between adjacent two of the trenches 6 (mesa region), and there may be mesa regions free of the n⁺-type emitter regions 3. Furthermore, the n⁺-type emitter regions 3 may be selectively disposed at predetermined intervals in the direction in which the trenches 6 extend in a stripe shape.

FIGS. 7, 8, 9, 10, and 11 are cross-sectional views schematically depicting electrode formation in the method of manufacturing the semiconductor device according to the first embodiment. After formation of the surface device structure, the interlayer insulating film 9 formed by two layers, for example, a BPSG film and an HTO film, is formed at the front surface of the semiconductor wafer 10 so as to cover the gate electrodes 8. Next, the interlayer insulating film 9 is patterned thereby forming multiple contact holes 20 that penetrate through the interlayer insulating film 9 in the depth direction. The state up to this point is depicted in FIG. 7. The depth direction is a direction from the front surface to the back surface of the semiconductor wafer 10. The n⁺-type emitter regions 3 and the p⁺-type contact regions 4 are exposed in the contact holes 20, in the IGBT region 21. The p-type base region 2 is exposed in the contact holes 20, in the FWD region 22. In FIGS. 7 to 11, the n⁺-type emitter regions 3, the p⁺-type contact regions 4, and the p-type base region 2 are not depicted, and only the semiconductor wafer 10 is depicted.

Next, a Ti film (initial barrier metal) 17 is uniformly formed in the contact holes 20 and on the surface of the interlayer insulating film 9 by sputtering. Next, a first TiN film (initial barrier metal) 18 is formed on the surface of the Ti film 17 by sputtering. The state up to this point is depicted in FIG. 8. Next, a third barrier metal 25c may be formed by chemically changing the initial barrier metal in contact with the semiconductor wafer 10 through heat treatment. Here, the chemical change may refer to the formation of an alloy with the underlying Si. Meanwhile, the second barrier metal 25b is formed in contact with the interlayer insulating film 9 using the initial barrier metal that has not been chemically changed by the heat treatment. Here, “no chemical change” does not mean no reaction at all and may also include a reaction that is slight compared to the reaction of the third barrier metal 25c, in which most of the Ti film forms an alloy with Si. For example, the heat treatment may be performed after the formation of the first TiN film 18, and this heat treatment may make the first TiN film 18 of the second barrier metal 25b denser than before the heat treatment. Furthermore, this heat treatment may be performed, for example, after the formation of the Ti film 17 but before the formation of the first TiN film 18. This heat treatment may chemically change the surface of the Ti film 17; for example, the surface of the Ti film 17 may react with the atmosphere, thereby forming a TiN film. That is, nitridation may occur as the chemical change.

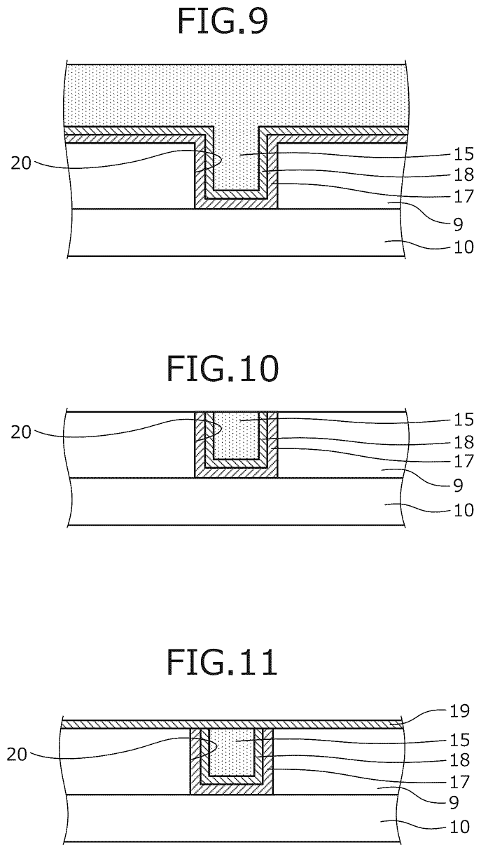

Next, the surface of the first TiN film 18 (second barrier metal 25b and third barrier metal 25c) and the contact holes 20 are embedded with the plug electrode 15 by, for example, CVD. The state up to this point is depicted in FIG. 9. Next, the plug electrode 15 outside the contact holes 20 is removed by etching, whereby the plug electrodes 15 are formed in the contact holes 20. Next, portions of the Ti film 17 and the first TiN film 18 (second barrier metal 25b) outside the contact holes 20 that are not covered by the plug electrodes 15 are removed by etching, leaving the second barrier metal 25b between the plug electrode 15 and the interlayer insulating film 9 in the contact holes 20. The state up to this point is depicted in FIG. 10.

Next, for example, the second TiN film 19 constituting the first barrier metal 25a, is uniformly formed on the surfaces of the interlayer insulating film 9 and the plug electrode 15 by sputtering. The state up to this point is depicted in FIG. 11. Thereafter, the second TiN film 19 on the plug electrode 15 may be removed, leaving only the second TiN film 19 on the interlayer insulating film 9. Next, a front surface metal film constituting the front electrode 11, is formed by sputtering, for example. The front surface metal film may contain aluminum containing 1% silicon (Al—Si), for example. Next, the front surface metal film is patterned. Next, the patterned front surface metal film is annealed in a hydrogen atmosphere, thereby forming the front electrode 11. This completes the formation of the electrode depicted in FIG. 2.

The front electrode 11 is electrically connected to the p-type base region 2, the n⁺-type emitter regions 3, and the p⁺-type contact regions 4 in the IGBT region 21 and functions as an emitter electrode. The front electrode 11 is also electrically connected to the p-type base region 2 in the FWD region 22 and functions as an anode electrode. The front electrode 11 may also be electrically connected to the p-type base region 2 in a mesa portion that is free of the n⁺-type emitter regions 3.

Next, the semiconductor wafer 10 is ground from the back side thereof to a position corresponding to the product thickness used for a semiconductor device. Next, a process including photolithography and ion implantation is repeated under different conditions thereby forming a back surface device structure at the back surface of the semiconductor wafer 10. For example, the n-type field stop layer 12, the n⁺-type cathode region 14, and the p⁺-type collector region 13 are formed.

The n⁺-type cathode region 14 is formed in the semiconductor wafer 10, at the back surface thereof after grinding, the n⁺-type cathode region 14 being formed in an entire area of the back surface of the semiconductor wafer 10. The n-type field stop layer 12 is formed at a position deeper from the back surface of the semiconductor wafer 10 after grinding than is the n⁺-type cathode region 14. The n-type field stop layer 12 is formed at least from the IGBT region 21 to the FWD region 22. The n-type field stop layer 12 may be in contact with the n⁺-type cathode region 14.

Next, a portion of the n⁺-type cathode region 14 corresponding to the IGBT region 21 is converted to a p⁺-type by photolithography and ion implantation, thereby forming the p⁺-type collector region 13. That is, the p⁺-type collector region 13 is in contact with the n⁺-type cathode region 14 in the direction in which the IGBT region 21 and the FWD region 22 are arranged. The p⁺-type collector region 13 may be in contact with the n-type field stop layer 12 in the depth direction.

Next, the p⁺-type collector region 13 and the n-type FS layer 12 are activated by heat treatment (annealing). Next, a passivation film is formed at the front surface of the semiconductor wafer 10 so as to cover the edge termination region. Next, the passivation film is patterned to expose the emitter electrode, the anode electrode, and each signal electrode pad.

Next, a photoresist film (not depicted) having an opening corresponding to the FWD region 22 is formed on the front surface of the semiconductor wafer 10. The opening may include the IGBT region 21. Using this photoresist film as a mask (shielding film), high-acceleration-energy, deep-range helium irradiation may be performed to introduce (form) helium defects that act as lifetime killers in the n⁻-type drift region 1, thereby forming the lifetime controlled region 26.

Then, the photoresist film is removed by ashing. Next, the back electrode 24 is formed in an entire area of the back surface of the semiconductor wafer 10. The back electrode 24 is in contact with the p⁺-type collector region 13 and the n⁺-type cathode region 14. The back electrode 24 functions as a collector electrode as well as a cathode electrode. The semiconductor wafer 10 is then cut (diced) into chips thereby forming individual RC-IGBT chips 150 (semiconductor chips).

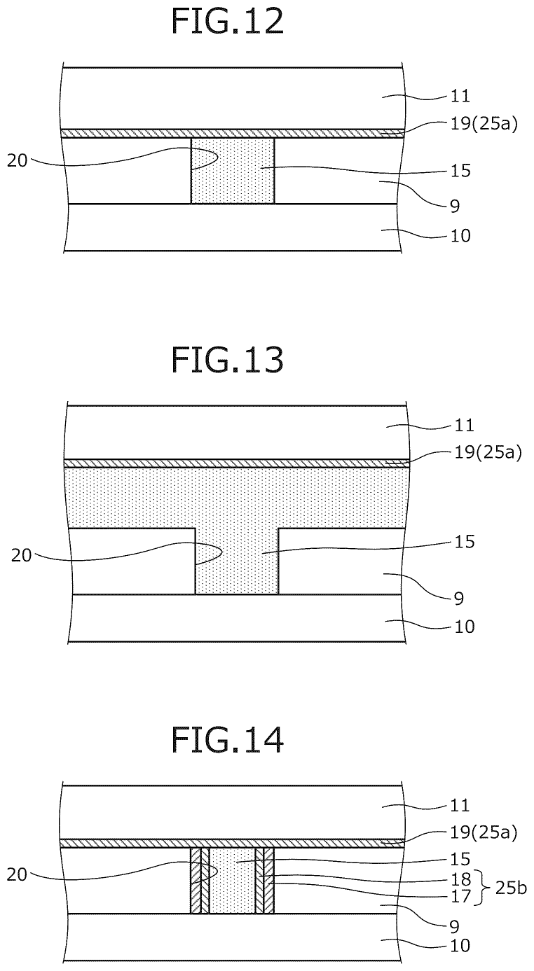

The electrodes of the semiconductor device according to the first embodiment are not limited to the structure depicted in FIG. 2. FIGS. 12, 13, 14, 15, 16, 17, and 18 are cross-sectional views depicting other structures of the electrodes of the semiconductor device according to the first embodiment. These other electrode structures also have an effect similar to that of the electrode structure depicted in FIG. 2. These structures are manufactured by appropriately modifying the manufacturing method described with reference to FIGS. 7, 8, 9, 10, and 11.

FIG. 12 depicts an instance in which the barrier metal 25 is only the first barrier metal 25a formed by the second TiN film 19. In other words, the second barrier metal 25b and the third barrier metal 25c are not provided within the contact holes 20. The first barrier metal 25a (second TiN film 19) is provided on the surfaces of the interlayer insulating film 9 and the plug electrodes 15.

FIG. 13 depicts an instance in which the barrier metal 25 is configured by only the first barrier metal 25a formed by the second TiN film 19, and the plug electrode 15 is also provided on the surface of the interlayer insulating film 9. The first barrier metal 25a is provided on the surface of the plug electrode 15, and the front electrode 11 is provided on the surface of the first barrier metal 25a.

FIG. 14 depicts an instance in which the barrier metal 25 is configured by the first barrier metal 25a formed by the second TiN film 19 and the second barrier metal 25b formed by the Ti film 17 and the first TiN film 18. In other words, the third barrier metal 25c is not provided between the plug electrode 15 and the semiconductor wafer 10.

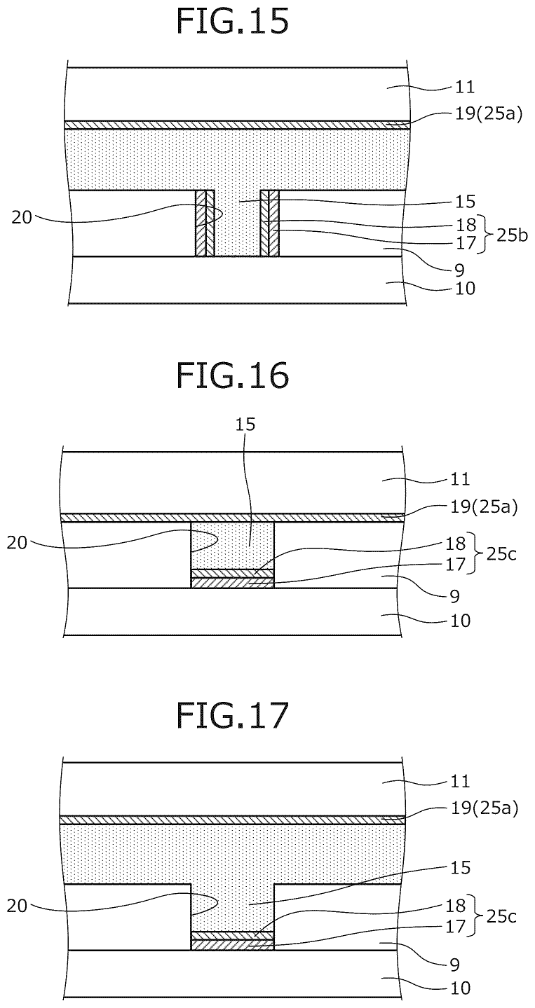

FIG. 15 depicts an instance in which the barrier metal 25 is configured by the first barrier metal 25a formed by the second TiN film 19 and the second barrier metal 25b formed by the Ti film 17 and the first TiN film 18, and in which the plug electrode 15 is also provided on the surface of the interlayer insulating film 9. The first barrier metal 25a is provided on the surface of the plug electrode 15, and the front electrode 11 is provided on the surface of the first barrier metal 25a.

FIG. 16 depicts an instance in which the barrier metal 25 is configured by the first barrier metal 25a formed by the second TiN film 19, and the third barrier metal 25c formed by the Ti film 17 and the first TiN film 18. In other words, the second barrier metal 25b is not provided between the side surface of the plug electrode 15 and the interlayer insulating film 9.

FIG. 17 depicts an instance in which the barrier metal 25 includes the first barrier metal 25a formed by the second TiN film 19, and the third barrier metal 25c formed by the Ti film 17 and the first TiN film 18, and in which the plug electrode 15 is also formed on the surface of the interlayer insulating film 9. The first barrier metal 25a is formed on the surface of the plug electrode 15, and the front electrode 11 is provided on the surface of the first barrier metal 25a.

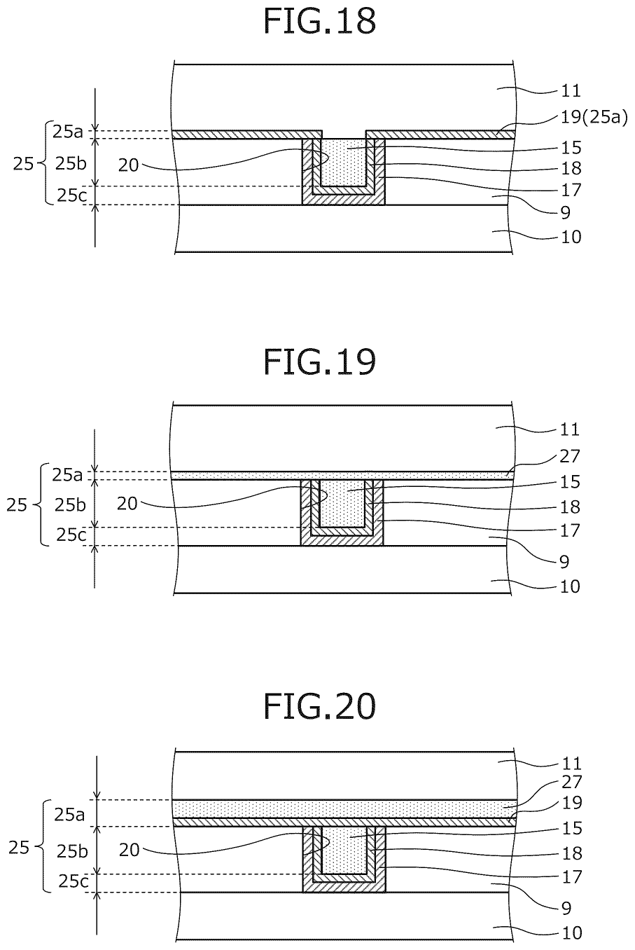

FIG. 18 depicts an instance in which the third barrier metal 25c formed by the Ti film 17 and the first TiN film 18, and the second barrier metal 25b are disposed, and in which the first barrier metal 25a (second TiN film 19) is not provided on the surface of the plug electrode 15. In other words, the front electrode 11 is provided on the surface of the plug electrode 15. The structure depicted in FIG. 18 is a configuration in which the first barrier metal 25a on the surface of the plug electrode 15 is selectively removed from the structure depicted in FIG. 2. This improves the adhesion between the plug electrode 15 and the front electrode 11. However, since the structure depicted in FIG. 18 has more processes and higher costs than the structure depicted in FIG. 2, the structure depicted in FIG. 2 is preferable.

As described above, according to the first embodiment, the absence of the Ti film on the interlayer insulating film curbs hydrogen absorption. This allows heat and hydrogen to be supplied to defective portions of the gate insulating film by annealing, thereby repairing the defects. This suppresses a decrease in Vth due to defects in the gate insulating film. Furthermore, by sandwiching a second TiN film between the interlayer insulating film and the front electrode, it is possible to prevent ions in the package resin from reaching the gate insulating film through defects in the front electrode. This suppresses a decrease in Vth due to defects in the front electrode.

FIG. 19 is a cross-sectional view depicting the structure of an electrode of a semiconductor device according to a second embodiment. In the second embodiment, the structure is the same as in the first embodiment except for the electrode structure and therefore, description of the element structure will be omitted (see FIG. 1). The second embodiment differs from the first embodiment in the first barrier metal 25a, while the structures of the second barrier metal 25b and the third barrier metal 25c are the same as those in the first embodiment.

In the second embodiment, the first barrier metal 25a formed on the plug electrode 15 and the interlayer insulating film 9 contains a metal element different from the metal elements contained in the second barrier metal 25b and the third barrier metal 25c. For example, in the structure depicted in FIG. 19, the first barrier metal 25a is formed using a W film 27 containing tungsten (W), which is not contained in the second barrier metal 25b or the third barrier metal 25c, and the first barrier metal 25a does not contain Ti, which is contained in the second barrier metal 25b and the third barrier metal 25c.

As depicted in FIG. 19, in the second embodiment, the plug electrode 15 contains W and thus, has a different metal element from Al of the front electrode 11, and first barrier metal 25a includes the W film 27, which contains the same metal element as the plug electrode 15.

A semiconductor device according to the second embodiment is formed in the same manner as the semiconductor device according to the first embodiment. First, as in the first embodiment, a surface device structure is formed, and then the interlayer insulating film 9 having two layers, for example, a BPSG film and an HTO film, is formed on the front surface of the semiconductor wafer 10 so as to cover gate electrodes 8. Next, the interlayer insulating film 9 is patterned thereby forming the contact holes 20 that penetrate through the interlayer insulating film 9 in the depth direction.

Next, the Ti film (initial barrier metal) 17 and the first TiN film (initial barrier metal) 18 are uniformly formed in the contact holes 20 and on the surface of the interlayer insulating film 9 by sputtering. Next, the third barrier metal 25c may be formed by chemically changing the initial barrier metal in contact with the semiconductor wafer 10, by a heat treatment. Furthermore, the second barrier metal 25b is formed by the initial barrier metal that was not chemically changed by the heat treatment and is in contact with the interlayer insulating film 9.

Next, the plug electrode 15 is deposited on the second barrier metal 25b and the third barrier metal 25c by, for example, CVD, so as to be embedded in the contact holes 20. Next, the plug electrode 15 above the upper surface of the interlayer insulating film 9 is removed, and then the second barrier metal 25b exposed above the upper surface of the interlayer insulating film 9 is removed, leaving portions of the second barrier metal 25b in the contact holes 20.

Next, in the case of FIG. 19, the W film 27 is uniformly formed on the surfaces of the interlayer insulating film 9 and the plug electrode 15 by, for example, sputtering. This forms the electrode structure depicted in FIG. 19. From this point onward, the processes are the same as in the first embodiment.

In the semiconductor device according to the second embodiment, the W film 27 is provided on the interlayer insulating film 9 and the plug electrode 15. W prevents ions contained in the package resin 16 from reaching the gate insulating film 7, thereby preventing a decrease in Vth attributable to the front electrode defects during packaging. Furthermore, W does not absorb hydrogen, curbing decreases in Vth due to defects in the gate insulating film after wafer processing. Similar effects may be achieved by using a tungsten nitride (WN) film, or a nitride film of simple film of tantalum (Ta), nickel (Ni), cobalt (Co), molybdenum (Mo), or the like, instead of the W film 27. While FIG. 19 depicts a structure comparable to that depicted in FIG. 2, the second embodiment may be applied in combination with the structures depicted in FIGS. 12 to 18. FIGS. 12 and 13 depict examples in which the second barrier metal 25b and the third barrier metal 25c are not included. However, as explained above, even when the first barrier metal 25a does not contain Ti, effects similar to those when the second barrier metal 25b and the third barrier metal 25c are included are achieved.

As described above, according to the second embodiment, the absence of a Ti film on the interlayer insulating film curbs hydrogen absorption. This allows heat and hydrogen to be supplied to defective portions of the gate insulating film by annealing, thereby repairing the defects. This makes it possible to suppress decreases in Vth due to defects in the gate insulating film. Furthermore, by sandwiching a W film between the interlayer insulating film and the front electrode, it is possible to suppress the arrival of ions in the package resin at the gate insulating film through defects in the front electrode. This makes it possible to suppress decreases in Vth due to defects in the front electrode.

FIG. 20 is a cross-sectional view depicting another structure of an electrode of a semiconductor device according to a third embodiment. The third embodiment differs from the first embodiment in that the first barrier metal 25a is formed by depositing multiple films, while the second barrier metal 25b and the third barrier metal 25c have the same structures as those of the first embodiment. For example, in the structure depicted in FIG. 20, the first barrier metal 25a has two layers: the second TiN film 19 containing the metal elements contained in the second barrier metal 25b and the third barrier metal 25c, and the W film 27 containing a different metal element. The two-layer structure of the second TiN film 19 and the W film 27 depicted in FIG. 20 may trap more ions than TiN alone. Furthermore, W deposited by CVD has poor adhesion to the interlayer insulating film 9 and may react with Ti exposed at the sidewall, causing defects. Therefore, forming the second TiN film 19 facilitates the formation of the W film 27. Furthermore, the multi-layer structure may improve ion trapping and mechanical strength.

Furthermore, the first barrier metal 25a is not limited to only TiN/W and may be a multi-layer film such as Ti/TIN, TiN/Ti/TIN, Ti/TiN/W, or TiN/Ti/TiN/W. While Ti is disadvantageous in terms of hydrogen absorption and preventing a decrease in Vth due to defects in the gate insulating film, a Ti film may be formed thinner than necessary for silicide formation to, thereby, improve the ion trapping performance of the package resin 16 and suppress decreases in Vth due to defects in the front electrode, provided that the decrease in Vth due to defects in the gate insulating film is not problematic. If the Ti film is relatively thin when the initial barrier metal that will become the third barrier metal 25c is deposited, silicide formation at the bottom of the contact holes 20 will be insufficient, resulting in high contact resistance. Therefore, preferably, a thick Ti film and a thin Ti film may be formed in two separate steps, once during the deposition of the initial barrier metal (Ti film 17) and once during the deposition of the first barrier metal 25a. A structure in which Ti is covered with TiN may prevent the Ti from being oxidized immediately when exposed to the atmosphere after deposition. Furthermore, a structure in which W is used to cover the Ti may protect the Ti from WF₆ and other gases used in W-CVD. On the other hand, a structure in which TiN is placed under Ti may improve mechanical strength because TiN has better adhesion to BPSG. While FIG. 20 depicts a structure that is contrasted with the structure depicted in FIG. 2, the third embodiment may be combined with the structures depicted in FIGS. 12, 13, 14, 15, 16, 17, and 18.

A semiconductor device according to the third embodiment is formed in the same manner as the semiconductor device according to the first or second embodiment. After the semiconductor device according to the first embodiment is similarly fabricated up to the state depicted in FIG. 10, the second TiN film 19 may be uniformly formed on the surfaces of the interlayer insulating film 9 and the plug electrode 15 by, for example, sputtering, and then the W film 27 may be formed on the second TiN film 19 by, for example, CVD or sputtering.

As described above, according to the third embodiment, a stacked film formed by multiple films is provided on the interlayer insulating film and the plug electrode. The absence or reduction of the Ti film on the interlayer insulating film curbs hydrogen absorption. This allows heat and hydrogen to be supplied to defective portions of the gate insulating film by annealing, thereby repairing the defects. This suppresses a decrease in Vth due to defects on the gate insulating film. It also suppresses arrival of ions in the package resin at the gate insulating film through defects in the front electrode. As a result, decreases in Vth caused by defects in the front electrode may be suppressed.

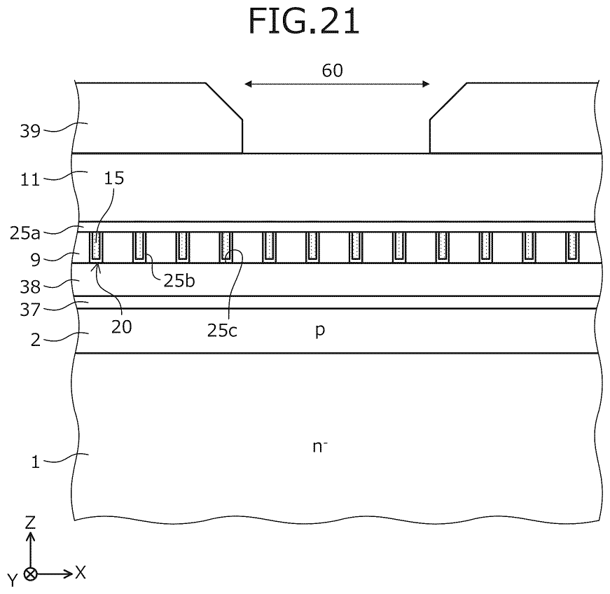

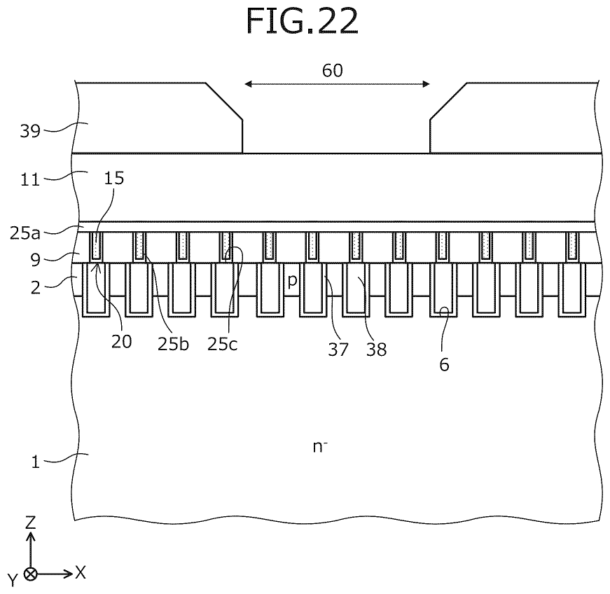

FIG. 21 is a cross-sectional view depicting the structure near the signal electrode pad of the semiconductor device according to a fourth embodiment. As depicted in FIG. 21, in the semiconductor device according to the fourth embodiment, the structure below the signal electrode pad is the same as the structure of the active region. That is, the barrier metal 25 is formed by the first barrier metal 25a formed on the plug electrode 15 and the interlayer insulating film 9, the second barrier metal 25b formed between the side surface of the plug electrode 15 and the interlayer insulating film 9, and the third barrier metal 25c formed between the plug electrode 15 and a connection portion 38. The connection portion 38 is provided below the contact holes 20 and the interlayer insulating film 9. When the signal electrode pad does not take the emitter electrode potential, the connection portion 38 is configured to not be at the emitter electrode potential. For example, an insulating film 37 may be provided below the connection portion 38. For example, in the case of a gate pad, the connection portion 38 may be a polycrystalline portion such as polysilicon, may be formed concurrently with the gate electrodes 8, and may be connected to the gate electrodes 8. Furthermore, the insulating film 37 may be formed concurrently with the gate insulating films 7. Furthermore, in the case of an anode/cathode electrode pad of a temperature-sensitive diode, the connection portion 38 may be a polycrystalline portion such as polysilicon, may be formed concurrently with the temperature-sensitive diode, and may be connected to the temperature-sensitive diode. Alternatively, the first barrier metal 25a may be formed concurrently with the gate electrodes 8 and may be apart from the temperature-sensitive diode. In FIG. 21, while the connection portion 38 and the insulating film 37 are formed to be continuous in a plan view, the connection portion 38 and the insulating film 37 may be formed to be apart from each other. Although the base region 2 is formed in the semiconductor wafer 10 below the insulating film 37, configuration is not limited hereto and other impurity regions, trenches, etc. may also be provided.

The first barrier metal 25a may be the second TiN film 19 as depicted in FIG. 2, the W film 27 as depicted in FIG. 19, or the stacked film of the second TiN film 19 and the W film 27 as depicted in FIG. 20. Furthermore, the structure of the barrier metal 25 may be any of the structures depicted in FIGS. 12, 13, 14, 15, 16, 17, and 18. The second barrier metal 25b and the third barrier metal 25c have the same structures as those in the first embodiment.

FIG. 22 is another cross-sectional view depicting the structure near the signal electrode pad of the semiconductor device according to the fourth embodiment. FIG. 22 differs from the example depicted in FIG. 21 in that the contact holes 20 provided in the interlayer insulating film 9 are present above the trenches 6 below a signal electrode pad 60. That is, in FIG. 22, the insulating film 37 is formed on the sidewalls of the trenches 6 formed on the first main surface side of the semiconductor wafer 10, and the connection portion 38 is provided in the trenches 6. The width of the bottom of the contact holes 20 is narrower than the width of the tops of the trenches 6, and may be wider or narrower than the width of the upper surface of the connection portion 38.

The trenches 6 may be formed concurrently with those of the active region, i.e., the trenches 6 depicted in FIG. 1, or may be formed separately. The insulating film 37 may be formed concurrently with the gate insulating films 7, or may be formed separately. The connection portion 38 may be a polycrystalline portion such as polysilicon, and may be formed concurrently with the gate electrodes 8, or may be formed separately. For example, in the case of a gate pad, the connection portion 38 may be connected to the gate electrodes 8, or the trenches 6 may extend to the active region and function as a gate, or the connection portion 38 may not be directly connected to the gate electrodes 8. Furthermore, for example, in the case of an anode/cathode electrode pad of a temperature-sensitive diode, the connection portion 38 may be a polycrystalline portion such as polysilicon, may be formed concurrently with the temperature-sensitive diode, and may be connected to the temperature-sensitive diode or may not be directly connected. Alternatively, the connection portion 38 may be formed concurrently with the gate electrodes 8 and not be connected to the temperature-sensitive diode.

Below a passivation film 39, similar to below the signal electrode pad 60, the connection portion 38 is formed in the trenches 6 and connected to the front electrode 11 via the contact holes 20 including the plug electrode 15, the second barrier metal 25b, and the third barrier metal 25c provided in the interlayer insulating film 9. For example, in the case of a gate pad, the front electrode 11 below the passivation film 39 may be a gate finger connecting the gate electrodes 8 and the gate pad, and the connection portion 38 may be the gate finger connecting the gate electrodes 8 and the gate pad, or the gate electrodes 8. In the case of anode/cathode electrode pads of a temperature-sensitive diode, the front electrode 11 below the passivation film 39 may be a runner connecting the temperature-sensitive diode to the anode/cathode electrode pad, and the connection portion 38 may be the temperature-sensitive diode. In another example, the connection portion 38, the contact holes 20 connecting to the connection portion 38, the insulating film 37, etc. may be absent below the passivation film 39. Furthermore, as with the structure depicted in FIG. 21, the insulating film 37, the connection portion 38, and the contact holes 20 may be provided above the semiconductor wafer 10.

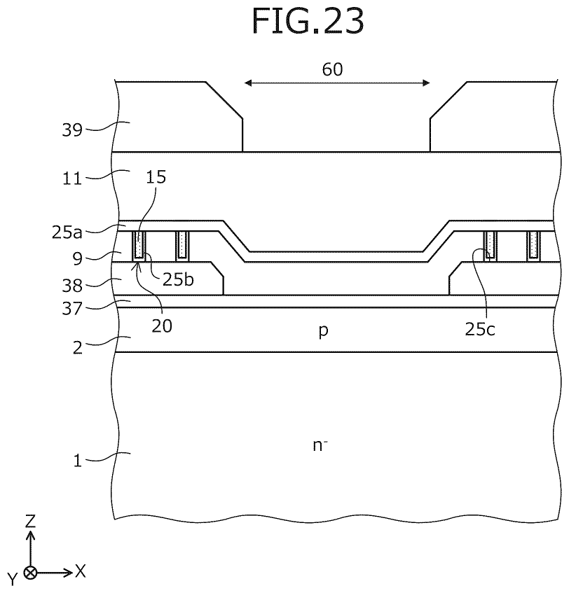

FIG. 23 is another cross-sectional view depicting the structure near the signal electrode pad of the semiconductor device according to the fourth embodiment. The example depicted in FIG. 23 differs from the examples depicted in FIGS. 21 and 22 in that the interlayer insulating film 9 does not have the contact holes 20 below the signal electrode pad 60. That is, in FIG. 23, the first barrier metal 25a is formed on the upper surface of the interlayer insulating film 9 below the signal electrode pad 60. In FIG. 23, there is no connection portion 38 below the signal electrode pad 60, but in another example, the connection portion 38 may lie below the interlayer insulating film 9.

Other structures may be the same as those depicted in FIG. 21 or 22. In FIG. 23, similar to that depicted in FIG. 21, the connection portion 38 lies below the passivation film 39, lies below the interlayer insulating film 9 having the first barrier metal 25a at the upper surface there, and is connected to the front electrode 11 via the contact holes 20 having the plug electrode 15, the second barrier metal 25b, and the third barrier metal 25c. For example, in the case of a gate pad, the front electrode 11 below the passivation film 39 may be a gate finger connecting the gate electrodes 8 and the gate pad, and the connection portion 38 may be the gate finger connecting the gate electrodes 8 and the gate pad, or the gate electrodes 8. In the case of anode/cathode electrode pads for a temperature-sensitive diode, the front electrode 11 below the passivation film 39 may be a runner connecting the temperature-sensitive diode to the anode/cathode electrode pad, and the connection portion 38 may be a temperature-sensitive diode. In another example, the connection portion 38, the contact holes 20 connecting to the connection portion 38, the insulating film 37, etc. may be absent below the passivation film 39. Alternatively, as depicted in FIG. 22, the contact holes 20 connecting to the connection portion 38 formed in the trenches 6 below the interlayer insulating film 9, may be provided in the interlayer insulating film 9.

In the semiconductor device according to the fourth embodiment, the first barrier metal 25a such as the second TiN film 19 or the W film 27 is provided on the interlayer insulating film 9, as in the first, second, or third embodiment. Eliminating or reducing the amount of Ti film on the interlayer insulating film curbs hydrogen absorption. This allows heat and hydrogen to be supplied to defective portions during annealing, thereby repairing the defects. This suppresses decreases in Vth due to defects. Furthermore, when the Ti film is not formed directly on the interlayer insulating film, mechanical strength is improved and peeling of the front electrode is prevented.

The semiconductor device according to the fourth embodiment may be manufactured by fabricating the structures below and above the barrier metal 25 using conventional manufacturing methods, and fabricating the barrier metal 25 using the manufacturing method of the first, second, or third embodiment.

That is, the insulating film 37 is formed on the upper surface or in the semiconductor wafer 10. Next, a polycrystalline portion such as polysilicon is formed on the insulating film 37 and patterned thereby forming the connection portion 38 and shaping the insulating film 37. Next, the interlayer insulating film 9 is formed above the connection portion 38 and the semiconductor wafer 10. Next, the contact holes 20 are formed, exposing the connection portion 38. Next, the Ti film (initial barrier metal) 17 is uniformly formed in the contact holes 20 and on the surface of the interlayer insulating film 9 by sputtering. Next, the first TiN film (initial barrier metal) 18 is formed on the surface of the Ti film 17 by sputtering. Next, the third barrier metal 25c may be formed by chemically changing the initial barrier metal in contact with the connection portion 38 by heat treatment. The second barrier metal 25b is formed in contact with the interlayer insulating film 9 by the initial barrier metal that has not been chemically changed by the heat treatment.

Next, the plug electrode 15 is formed at the surface of the first TiN film 18 (second barrier metal 25b and third barrier metal 25c) and is embedded in the contact holes 20 by, for example, sputtering. Next, portions of the plug electrode 15 outside the contact holes 20 are removed by etching, thereby forming the plug electrode 15 in the contact holes 20. Next, portions of the Ti film 17 and the first TiN film 18 (second barrier metal 25b) outside the contact holes 20, which are not covered by the plug electrode 15, are removed by etching, leaving the second barrier metal 25b between the plug electrode 15 and the interlayer insulating film 9 in the contact holes 20. Next, for example, the first barrier metal 25a is formed uniformly on the surfaces of the interlayer insulating film 9 and the plug electrode 15. That is, the second TiN film 19 is formed by sputtering and the W film 27 is formed by CVD, or the second TIN film 19 and the W film 27 are formed by sputtering. Thereafter, the first barrier metal 25a on the plug electrode 15 may be removed, leaving the first barrier metal 25a only on the interlayer insulating film 9. Next, a front surface metal film that will become the front electrode 11 is formed by, for example, sputtering. Next, the front surface metal film is patterned. Next, the patterned front-surface metal film is annealed in a hydrogen atmosphere thereby forming the front electrode 11. In a subsequent process, the passivation film 39 is formed on the front surface of the semiconductor wafer 10, and the passivation film 39 is patterned to expose the signal electrode pad 60. This results in the formation of the signal electrode pad 60 and the structure nearby, as depicted in FIGS. 21, 22, and 23. Some or all of the above processes may be performed in common with the process of forming the active region depicted in FIG. 1. Note that when no contact holes 20 are below the signal electrode pad 60 depicted in FIG. 23, the processes related to the inside of the contact holes 20, i.e., the formation of the contact holes 20 and the formation of the third barrier metal 25c, may be performed below the passivation film 39 or in the active region outside the signal electrode pad 60. The second barrier metal 25b and the plug electrode 15 may be provided below the signal electrode pad 60 during manufacturing but removed at completion.

As described above, according to the fourth embodiment, a first barrier metal such as a second TiN film or a W film is provided on the interlayer insulating film, as in the first, second, and third embodiments. The absence or reduction of the Ti film on the interlayer insulating film curbs hydrogen absorption. Annealing thereby supplies heat and hydrogen to defective portions of the gate insulating film, allowing the defects to be repaired. This suppresses decreases in Vth due to defects on the gate insulating film. Furthermore, it is possible to prevent ions in the package resin from reaching the gate insulating film through defects in the front electrode. This suppresses decreases in Vth due to defects in the front electrode. Furthermore, when a Ti film is not formed directly on the interlayer insulating film, mechanical strength is improved, preventing peeling of the front electrode.

While the present disclosure has been described above with reference to an example in which a MOS gate structure is configured on the first main surface of a silicon substrate, the present disclosure is not limited hereto. The type of semiconductor (e.g., silicon carbide (SiC)), the surface orientation of the substrate main surface, and other factors may be variously modified. Although the embodiments of the present disclosure have been described using a trench-type IGBT as an example, the present disclosure is not limited hereto and may be applied to semiconductor devices with various configurations, such as planar-type IGBTs and MOS semiconductor devices such as MOSFETs. The barrier metal structure of the present disclosure is not limited to the mesa portion of the active region in FIG. 1 or below or near the signal electrode pads in FIGS. 21, 22, and 23, and may also be applied to other interlayer insulating films and contact holes. In this case, the front electrode above the first barrier metal is not limited to one that is exposed or one that conducts power. For example, the present disclosure may be applied to a contact hole provided in an interlayer insulating film that connects a gate finger or emitter electrode to a gate electrode in a trench, a field plate in an edge termination region, or a Zener diode. Furthermore, although the first conductivity type is n-type and the second conductivity type is p-type in the embodiments of the present disclosure, the present disclosure is similarly implemented when the first conductivity type is a p-type and the second conductivity type is an n-type.

The semiconductor device, the semiconductor module, and the method of manufacturing a semiconductor device according to the present disclosure have an advantage of being able to suppress decreases in Vth caused by front electrode defects and defects on the gate insulating film.

As described above, the semiconductor device, the semiconductor module, and the method of manufacturing a semiconductor device according to the present disclosure are useful for high-voltage semiconductor devices used in, for example, power converting equipment and power supply devices for various industrial machines.

Furthermore, the following Notes regarding the described embodiments are disclosed.

Note 1: A semiconductor device includes: a semiconductor substrate having a main surface; an interlayer insulating film provided on the main surface of the semiconductor substrate; a contact hole penetrating through the interlayer insulating film to reach the semiconductor substrate;
a plug electrode embedded in the contact hole;

a first barrier metal provided on the interlayer insulating film, the first barrier metal being apart from the plug electrode; and a front electrode provided on the first barrier metal and the plug electrode.

Note 2: The semiconductor device according to Note 1, further includes a second barrier metal provided between a side surface of the plug electrode and the interlayer insulating film.

Note 3: The semiconductor device according to Note 1, further includes a third barrier metal provided between the plug electrode and the semiconductor substrate.

Note 4: A semiconductor device includes: a semiconductor substrate having a main surface; an interlayer insulating film provided on the main surface of the semiconductor substrate; a contact hole penetrating through the interlayer insulating film to reach the semiconductor substrate; a plug electrode embedded in the contact hole; a first barrier metal provided on the interlayer insulating film; a second barrier metal provided between a side surface of the plug electrode and the interlayer insulating film; a third barrier metal provided between the plug electrode and the semiconductor substrate; and a front electrode provided on the first barrier metal. A top of the plug electrode is free of the first barrier metal, and the first barrier metal, the second barrier metal, and the third barrier metal have different compositions.

Note 5: In the semiconductor device according to Note 4, the first barrier metal is provided between the front electrode and the plug electrode.

Note 6: In the semiconductor device according to Note 1 or 4: the main surface of the semiconductor substrate is a first main surface, the semiconductor substrate further having a second main surface opposite to the first main surface, and the semiconductor device comprises a back electrode provided on the second main surface of the semiconductor substrate.

Note 7: The semiconductor device according to Note 1 or 4, further includes: a gate electrode at the main surface of the semiconductor substrate, insulated from the front electrode by the interlayer insulating film; a gate insulating film insulating the gate electrode from the semiconductor substrate; and a first dopant layer of a conductivity type complementary to that of the semiconductor substrate, the first dopant layer being selectively provided in the semiconductor substrate, in contact with the gate insulating film, wherein the first dopant layer is electrically connected to the front electrode via the contact hole.

Note 8: In the semiconductor device according to Note 7, the gate electrode is provided in a trench recessed from the main surface of the semiconductor substrate.

Note 9: The semiconductor device according to Note 7, further includes a second dopant layer selectively provided in the first dopant layer, the second dopant layer having a dopant concentration higher than that of the semiconductor substrate. The second dopant layer is in contact with the gate insulating film and electrically connected to the front electrode via the contact hole.

Note 10: The semiconductor device according to Note 1 or 4, further includes a lifetime controlled region having a controlled lifetime, provided in the semiconductor substrate.

Note 11: In the semiconductor device according to Note 1 or 4, the front electrode is a metal primarily containing aluminum (Al).

Note 12: In the semiconductor device according to Note 1 or 4, the front electrode includes a stacked structure of tungsten (W) and a metal primarily containing Al, sequentially from the first barrier metal.

Note 13: In the semiconductor device according to Note 1 or 4, the first barrier metal is titanium nitride (TiN).

Note 14: In the semiconductor device according to Note 1 or 4, the plug electrode is W.

Note 15: In the semiconductor device according to Note 4, the second barrier metal is formed of stacked layers of titanium (Ti) and TiN.

Note 16: A semiconductor module includes the semiconductor device according to Note 1 or 4 and a conductive wire is bonded to the front electrode.

Note 17: In the semiconductor module according to Note 16, the conductive wire is a metal primarily containing Cu.

Note 18: A semiconductor module includes the semiconductor device according to Note 1 or 4, sealed with resin.

Note 19: A method of manufacturing a semiconductor device, the method including: as a first process, preparing a semiconductor substrate and depositing an interlayer insulating film on a main surface of the semiconductor substrate; as a second process, forming a contact hole penetrating through the interlayer insulating film to reach the semiconductor substrate; as a third process, depositing a plug electrode on the interlayer insulating film and in the contact hole; as a fourth process, removing the plug electrode on the interlayer insulating film while leaving the plug electrode only in the contact hole; as a fifth process, depositing a first barrier metal on the plug electrode and the interlayer insulating film; as a tenth process, removing the first barrier metal on the plug electrode while leaving the first barrier metal only on the interlayer insulating film; and as a sixth process, depositing a front electrode on the first barrier metal, said first to sixth processes being performed in sequence as mentioned.

Note 20: A method of manufacturing a semiconductor device, the method includes: as a first process, preparing a semiconductor substrate and depositing an interlayer insulating film on a main surface of the semiconductor substrate; as a second process, forming a contact hole penetrating through the interlayer insulating film to the semiconductor substrate; as a third process, depositing a plug electrode on the interlayer insulating film and in the contact hole; as a fourth process, depositing a first barrier metal on the plug electrode and the interlayer insulating film; as a tenth process, removing the first barrier metal on the plug electrode while leaving the first barrier metal only on the interlayer insulating film; and as a fifth process, depositing a front electrode on the first barrier metal, said processes being performed in sequence as mentioned.

Note 21: A method of manufacturing a semiconductor device, the method includes: as a first process, preparing a semiconductor substrate and depositing an interlayer insulating film on a main surface of the semiconductor substrate; as a second process, forming a contact hole penetrating through the interlayer insulating film to the semiconductor substrate;

as a third process, depositing an initial barrier metal on the interlayer insulating film and in the contact hole; as a fourth process, performing a heat treatment thereby chemically changing the initial barrier metal in contact with the semiconductor substrate and forming a third barrier metal while forming a second barrier metal from the initial barrier metal that has not undergone chemical change; as a fifth process, depositing a plug electrode on the second barrier metal and the third barrier metal; as a sixth process, removing the plug electrode on the interlayer insulating film while leaving the plug electrode only in the contact hole; as a seventh process, removing the second barrier metal on the interlayer insulating film while leaving the second barrier metal only in the contact hole; as an eighth process, depositing a first barrier metal on the plug electrode and the interlayer insulating film; as a tenth process, removing the first barrier metal on the plug electrode while leaving the first barrier metal only on the interlayer insulating film; and as a ninth process, depositing a front electrode on the first barrier metal, said processes being performed in the order mentioned.

Note 22: The method of manufacturing a semiconductor device according to any one of Notes 19 to 21, further includes as an eleventh process, forming a lifetime controlled region having a controlled lifetime, in the semiconductor substrate by irradiation of a particle beam.

Note 23: In the semiconductor device according to Note 4, the first barrier metal contains a metal element different from a metal element contained in the second barrier metal.

Note 24: In the semiconductor device according to Note 4, the third barrier metal contains a metal element different from a metal element contained in the second barrier metal.

Note 25: In the semiconductor device according to Note 1 or 4, the first barrier metal is formed of a plurality of deposited layers.

Note 26: In the semiconductor device according to Note 23 or 24, the plug electrode and the surface electrode have different metal elements from each other, and the first barrier metal has a same metal element as the plug electrode.

Note 27: In the semiconductor device according to Note 23, the first barrier metal is formed of stacked layers including a first layer containing a metal element contained in the second barrier metal and a second layer containing a same metal element as the plug electrode.

Note 28: In the semiconductor device according to Note 24, the first barrier metal is formed of stacked layers including a first layer containing a metal element contained in the third barrier metal and a second layer containing a metal element contained in the plug electrode.

Note 29: In the method of manufacturing a semiconductor device according to Note 21, in the eighth process, the first barrier metal contains a metal element different from a metal element contained in the initial barrier metal.

Note 30: In the method of manufacturing a semiconductor device according to Note 21, the eighth process includes depositing, as the first barrier metal, a first layer containing a metal element contained in the initial barrier metal and a second layer containing a different metal element.

Note 31: In the method of manufacturing a semiconductor device according to Note 21, in the eighth process, the first barrier metal contains a same metal element as the plug electrode, and the ninth process includes depositing, as the front electrode, a film containing a metal element different from a metal element contained in the plug electrode.

Note 32: In the method of manufacturing a semiconductor device according to Note 21, the eighth process includes depositing, as the first barrier metal, a first layer containing a metal element contained in the initial barrier metal and a second layer containing a metal element contained in the plug electrode, and the ninth process includes depositing, as the front electrode, a film containing a metal element different from a metal element contained in the plug electrode.

Note 33: A semiconductor device includes: a semiconductor substrate; a polycrystalline portion provided above or at a first main surface of the semiconductor substrate; an interlayer insulating film provided on the polycrystalline portion; a contact hole penetrating through the interlayer insulating film to the polycrystalline portion; a plug electrode embedded in the contact hole; a first barrier metal provided on the interlayer insulating film without being provided on the plug electrode; and a front electrode provided on the first barrier metal and the plug electrode.

Note 34: A semiconductor device includes: a semiconductor substrate; a polycrystalline portion provided above or at a first main surface of the semiconductor substrate; an interlayer insulating film provided on the polycrystalline portion; a contact hole penetrating through the interlayer insulating film to the polycrystalline portion;
a plug electrode embedded in the contact hole; a first barrier metal provided on the interlayer insulating film; a second barrier metal provided between a side surface of the plug electrode and the interlayer insulating film; a third barrier metal provided between the plug electrode and the polycrystalline portion; and a front electrode provided on the first barrier metal. A top of the plug electrode is free of the first barrier metal, and the first barrier metal, the second barrier metal, and the third barrier metal each have a different composition.

Note 35: A method of manufacturing a semiconductor device, the method includes: as a twelfth process, forming a polycrystalline portion above or at a first main surface of a semiconductor substrate; as a first process, depositing an interlayer insulating film on the polycrystalline portion; as a second process, forming a contact hole that penetrates through the interlayer insulating film to the polycrystalline portion; as a third process, depositing a plug electrode on the interlayer insulating film and in the contact hole; as a fourth process, removing the plug electrode on the interlayer insulating film while leaving the plug electrode only in the contact hole; as a fifth process, depositing a first barrier metal on the plug electrode and the interlayer insulating film;
as a tenth process, removing the first barrier metal on the plug electrode while leaving the first barrier metal only on the interlayer insulating film; and as a sixth process, depositing a front electrode on the first barrier metal, said processes being performed in sequence as mentioned.

Note 36: A method of manufacturing a semiconductor device, includes: as a twelfth process, forming a polycrystalline portion above or at a first main surface of a semiconductor substrate; as a first process, depositing an interlayer insulating film on the polycrystalline portion;
as a second process, forming a contact hole that penetrates through the interlayer insulating film to the polycrystalline portion; as a third process, depositing a plug electrode on the interlayer insulating film and in the contact hole; as a fourth process, depositing a first barrier metal on the plug electrode and the interlayer insulating film; as a tenth process, removing the first barrier metal on the plug electrode while leaving the first barrier metal only on the interlayer insulating film; and as a fifth process, depositing a front electrode on the first barrier metal, said processes being performed in sequence as mentioned.

Note 37: A method of manufacturing a semiconductor device, the method includes: as a twelfth process, forming a polycrystalline portion above or at a first main surface of a semiconductor substrate; as a first process, depositing an interlayer insulating film on the polycrystalline portion; as a second process, forming a contact hole that penetrates through the interlayer insulating film to the polycrystalline portion; as a third process, depositing an initial barrier metal on the interlayer insulating film and in the contact hole; as a fourth process, performing a heat treatment chemically changing the initial barrier metal in contact with the polycrystalline portion and thereby forming a third barrier metal while forming a second barrier metal from the initial barrier metal that has not undergone chemical change; as a fifth process, depositing a plug electrode on the second barrier metal and the third barrier metal; as a sixth process, removing the plug electrode on the interlayer insulating film while leaving the plug electrode only in the contact hole; as a seventh process, removing the second barrier metal on the interlayer insulating film while leaving the second barrier metal only in the contact hole; as an eighth process, depositing a first barrier metal on the plug electrode and the interlayer insulating film;
as a tenth process, removing the first barrier metal on the plug electrode while leaving the first barrier metal only on the interlayer insulating film; and as a ninth process, stacking a front electrode on the first barrier metal, said processes being performed in sequence as mentioned.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor substrate having a main surface;
an interlayer insulating film provided on the main surface of the semiconductor substrate;
a contact hole penetrating through the interlayer insulating film to reach the semiconductor substrate;
a plug electrode embedded in the contact hole;
a first barrier metal provided on the interlayer insulating film, the first barrier metal being apart from the plug electrode; and
a front electrode provided on the first barrier metal and the plug electrode.

2. The semiconductor device according to claim 1, further comprising:
a second barrier metal provided between a side surface of the plug electrode and the interlayer insulating film.

3. The semiconductor device according to claim 1, further comprising:
a third barrier metal provided between the plug electrode and the semiconductor substrate.

4. The semiconductor device according to claim 1, wherein:
the main surface of the semiconductor substrate is a first main surface, the semiconductor substrate further having a second main surface opposite to the first main surface, and
the semiconductor device further includes a back electrode provided on the second main surface of the semiconductor substrate.

5. The semiconductor device according to claim 1, further comprising:
a gate electrode at the main surface of the semiconductor substrate, insulated from the front electrode by the interlayer insulating film;
a gate insulating film insulating the gate electrode from the semiconductor substrate; and
a first dopant layer of a conductivity type complementary to that of the semiconductor substrate, the first dopant layer being selectively provided in the semiconductor substrate, in contact with the gate insulating film, wherein
the first dopant layer is electrically connected to the front electrode via the contact hole.

6. The semiconductor device according to claim 5, wherein
the gate electrode is provided in a trench recessed from the main surface of the semiconductor substrate.

7. The semiconductor device according to claim 5, further comprising:
a second dopant layer selectively provided in the first dopant layer, the second dopant layer having a dopant concentration higher than that of the semiconductor substrate, wherein
the second dopant layer is in contact with the gate insulating film and is electrically connected to the front electrode via the contact hole.

8. The semiconductor device according to claim 1, further comprising:
a lifetime controlled region having a controlled lifetime, provided in the semiconductor substrate.

9. The semiconductor device according to claim 1, wherein
the front electrode is formed of a metal primarily containing aluminum (Al).

10. The semiconductor device according to claim 1, wherein
the front electrode includes a stacked structure of tungsten (W) and a metal primarily containing Al, sequentially from the first barrier metal.

11. The semiconductor device according to claim 1, wherein
the first barrier metal is titanium nitride (TiN).

12. The semiconductor device according to claim 1, wherein
the plug electrode is formed of tungsten (W).

13. A semiconductor module comprising the semiconductor device according to claim 1, sealed with resin.

14. A semiconductor device comprising:
a semiconductor substrate having a main surface;
an interlayer insulating film provided on the main surface of the semiconductor substrate;
a contact hole penetrating through the interlayer insulating film to reach the semiconductor substrate;
a plug electrode embedded in the contact hole;
a first barrier metal provided on the interlayer insulating film;
a second barrier metal provided between a side surface of the plug electrode and the interlayer insulating film;
a third barrier metal provided between the plug electrode and the semiconductor substrate; and
a front electrode provided on the first barrier metal, wherein
a top of the plug electrode is free of the first barrier metal, and
the first barrier metal, the second barrier metal, and the third barrier metal have different compositions.

15. The semiconductor device according to claim 14, wherein
the first barrier metal is provided between the front electrode and the plug electrode.

16. The semiconductor device according to claim 14, wherein
the second barrier metal is formed of stacked layers of titanium (Ti) and TiN.

17. A semiconductor module comprising the semiconductor device according to claim 14, wherein
a conductive wire is bonded to the front electrode.

18. The semiconductor module according to claim 17, wherein
the conductive wire is a metal primarily containing Cu.

19. A method of manufacturing a semiconductor device, the method comprising:
as a first process, preparing a semiconductor substrate and depositing an interlayer insulating film on a main surface of the semiconductor substrate;
as a second process, forming a contact hole penetrating through the interlayer insulating film to reach the semiconductor substrate;
as a third process, depositing a plug electrode on the interlayer insulating film and in the contact hole;
as a fourth process, removing the plug electrode on the interlayer insulating film while leaving the plug electrode only in the contact hole;
as a fifth process, depositing a first barrier metal on the plug electrode and the interlayer insulating film;
as a tenth process, removing the first barrier metal on the plug electrode while leaving the first barrier metal only on the interlayer insulating film; and
as a sixth process, depositing a front electrode on the first barrier metal,
said first to sixth processes being performed in sequence as mentioned.
